(19) United States
(12) Patent Application Publication
(10) Pub. No.: US 2026/0062808 A1
(43) Pub. Date: Mar. 5, 2026

(54) ATOMIC LAYER DEPOSITION APPARATUS

(71) Applicant: Samsung Electronics Co., Ltd., Suwon-si (KR)

(72) Inventors: Seokjun Hong, Suwon-si (KR); Sangchul Han, Suwon-si (KR); Donghyun Ko, Suwon-si (KR); Yihwan Kim, Suwon-si (KR); Taehee Yoo, Suwon-si (KR); Junho Lee, Suwon-si (KR)

(21) Appl. No.: 19/056,519

(22) Filed: Feb. 18, 2025

(30) Foreign Application Priority Data
Aug. 29, 2024 (KR) 10-2024-0116943

(51) Int. Cl. C23C 16/455; C23C 16/452; C23C 16/458; C23C 16/52; H01J 37/32

(52) U.S. Cl. CPC C23C 16/45565; C23C 16/452; C23C 16/45536; C23C 16/4586; C23C 16/52; H01J 37/32174; H01J 2237/3321; H01J 2237/3323; H01J 2237/3327; H01J 2237/3341; H01J 2237/3346

(57) ABSTRACT

An atomic layer deposition (ALD) apparatus includes a gas supply source configured to supply a first gas and a second gas, an upper plasma chamber configured to receive the first gas and generate first radicals and first ions, a main chamber disposed below the upper plasma chamber, an ion-blocking structure disposed between the upper plasma chamber and the main chamber, and configured to allow movement of the first radicals from the upper plasma chamber toward the main chamber, and block movement of the first ions, and a shower head disposed between the main chamber and the ion-blocking structure and including a plurality of first holes and a plurality of second holes, wherein the plurality of first holes are configured to supply the first radicals into the main chamber, the plurality of second holes are configured to supply the second gas into the main chamber.

### CROSS-REFERENCE TO RELATED APPLICATION

This application is based on and claims priority under 35 U.S.C. § 119 to Korean Patent Application No. 10-2024-0116943, filed on Aug. 29, 2024, in the Korean Intellectual Property Office, the disclosure of which is incorporated by reference herein in its entirety.

### BACKGROUND

The inventive concept relates to an atomic layer deposition (ALD) apparatus, and more particularly, to an ALD apparatus that performs a process of filling a gap of a trench.

An ALD process is a process of depositing a film on a wafer by using a precursor gas and a reaction gas. For example, a precursor layer adsorbed on a wafer disposed inside a chamber may be formed by supplying a precursor gas into the chamber for a certain period of time. Thereafter, when a reaction gas is supplied into the chamber for a certain period of time to react with the precursor layer, an atomic layer with a certain thickness may be generated on a surface of the wafer. Such an ALD process may provide good step coverages.

However, when the ALD process is performed to fill gaps of high-aspect-ratio trenches, voids may be formed in the trenches.

### SUMMARY

Aspects of the inventive concept provide an atomic layer deposition (ALD) apparatus that uniformly fills a gap of a high aspect ratio trench without generating voids in the trench.

However, issues addressed by the inventive concept are not limited to the problems mentioned above, and other issues may be clearly understood by those skilled in the art from the following description.

According to an aspect of the inventive concept, there is provided an ALD apparatus including a gas supply source configured to respectively supply a first gas and a second gas to a first gas supply pipe and a second gas supply pipe, an upper plasma chamber configured to receive the first gas from the first gas supply pipe and generate first radicals and first ions, a main chamber disposed below the upper plasma chamber, an electrostatic chuck configured to accommodate a wafer and disposed at a bottom of the main chamber, an ion-blocking structure disposed between the upper plasma chamber and the main chamber, and configured to allow movement of the first radicals from the upper plasma chamber toward the main chamber, and block movement of the first ions, and a shower head disposed between the main chamber and the ion-blocking structure and including a plurality of first holes and a plurality of second holes, wherein the plurality of first holes penetrate from an upper surface of the shower head to a lower surface of the shower head, and are configured to supply the first radicals into the main chamber, and the plurality of second holes are configured to supply, into the main chamber, the second gas supplied from the second gas supply pipe.

According to another aspect of the inventive concept, there is provided an ALD apparatus including a main chamber, a gas supply source configured to respectively supply a first gas and a second gas to a first gas supply pipe and a second gas supply pipe, an electrostatic chuck configured to accommodate a wafer and disposed at a bottom of the main chamber, an upper plasma chamber disposed at a top of the main chamber and configured to receive the first gas from the first gas supply pipe, an ion-blocking structure disposed between the main chamber and the upper plasma chamber and configured to block a movement of ions from the upper plasma chamber toward the main chamber, a shower head disposed between the ion-blocking structure and the main chamber and including a plurality of first holes and a plurality of second holes, a first plasma ignition apparatus configured to generate an upper plasma inside the upper plasma chamber, and a second plasma ignition apparatus configured to generate main plasma inside the main chamber, wherein the upper plasma includes first radicals and first ions corresponding to the first gas, the main plasma includes second radicals and second ions corresponding to the second gas, the plurality of first holes are configured to supply the first radicals into the main chamber, and the plurality of second holes are configured to supply a gas supplied from the second gas supply pipe into the main chamber.

According to another aspect of the inventive concept, there is provided an ALD apparatus including a gas supply source configured to respectively supply a first gas and a second gas to a first gas supply pipe and a second gas supply pipe, an upper plasma chamber to receive the first gas from the first gas supply pipe, a main chamber disposed below the upper plasma chamber, an ion-blocking structure disposed between the upper plasma chamber and the main chamber, and configured to block a movement of ions from the upper plasma chamber toward the main chamber, a shower head in contact with a lower surface of the ion-blocking structure and including a plurality of first holes and a plurality of second holes, an electrostatic chuck disposed at a bottom of the main chamber and configured to fix a wafer, a bias power supply configured to apply a bias potential to the wafer, a first plasma ignition apparatus configured to generate upper plasma inside the upper plasma chamber, and a second plasma ignition apparatus configured to generate main plasma inside the main chamber, wherein the upper plasma includes first radicals and first ions corresponding to gas supplied from the first gas supply pipe, the main plasma includes second radicals and second ions corresponding to gas supplied from the second gas supply pipe, the plurality of first holes are configured to supply the first radicals into the main chamber, and the plurality of second holes are configured to supply the gas supplied from the second gas supply pipe into the main chamber.

### BRIEF DESCRIPTION OF THE DRAWINGS

Embodiments will be more clearly understood from the following detailed description taken in conjunction with the accompanying drawings in which:

FIG. 1 is a cross-sectional view illustrating an atomic layer deposition (ALD) apparatus according to an embodiment;

FIGS. 2A to 2C are cross-sectional views and a perspective view, for describing an ion-blocking structure and a shower head, according to an embodiment;

FIGS. 3A to 3D are cross-sectional views illustrating an operating method of an ALD apparatus according to an embodiment;

FIG. 4 is a cross-sectional diagram for describing a trench existing on a wafer according to an embodiment;

FIG. 5 is a diagram for describing a bottom gap filling process according to an embodiment;

FIG. 6 is a diagram for describing a top gap filling process according to an embodiment;

FIGS. 7A to 7C are views for describing an overhang etching process according to an embodiment;

FIG. 8 is a flowchart illustrating a method of filling a gap in a trench, according to an embodiment;

FIG. 9 is a flowchart for describing a method of filling a bottom gap of a trench, according to an embodiment; and

FIG. 10 is a flowchart for describing a method of filling a top gap of a trench, according to an embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

Herein, a horizontal direction may include a first horizontal direction (X direction) and a second horizontal direction (Y direction) which intersect each other. A direction which intersects the first horizontal direction (X direction) and the second horizontal direction (Y direction) may be referred to as a vertical direction (Z direction). Herein, a vertical level may be referred to as a height level according to the vertical direction (Z direction) of any configuration.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

Terms such as “same,” “equal,” etc. as used herein encompass identicality or near identicality including variations that may occur, for example, due to manufacturing processes. The term “substantially” may be used herein to emphasize this meaning, unless the context or other statements indicate otherwise.

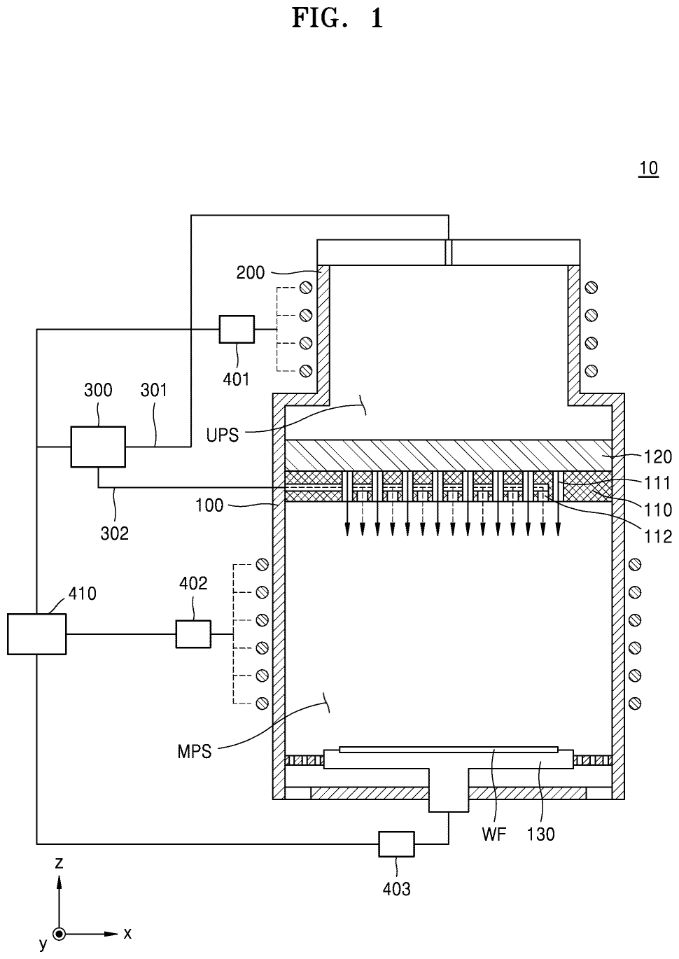

FIG. 1 is a cross-sectional view illustrating an atomic layer deposition (ALD) apparatus 10 according to an embodiment.

Referring to FIG. 1, an ALD apparatus 10 according to an embodiment may include a main chamber 100, a shower head 110, an ion-blocking structure 120, an electrostatic chuck 130, an upper plasma chamber 200, a gas supply source 300, a first plasma ignition apparatus 401, a second plasma ignition apparatus 402, and a bias power source 403.

The main chamber 100 may have an inner space having a certain size and may include a material having excellent wear resistance and corrosion resistance. The main chamber 100 may include a main chamber housing enclosing a main plasma formation space MPS. The main chamber 100 may be configured as, for example, an aluminum block. For example, the main chamber housing may be formed of aluminum. The main chamber 100 may maintain the inner space in a sealed state or a vacuum state in a plasma treatment process (e.g., a plasma enhanced ALD (PEALD) process).

The main chamber 100 may limit/define the main plasma formation space MPS, and be implemented in a cylindrical shape. The main plasma formation space MPS may be a space in which main plasma is formed. Here, the main plasma may be a plasma generated by discharging gas supplied from a second gas supply pipe 302 by the second plasma ignition apparatus 402. The main plasma may include second radicals and second ions corresponding to the gas supplied from the second gas supply pipe 302.

In the present disclosure, the term “radicals corresponding to a gas” may be radicals when gaseous particles of the gas receive high energy and are converted into particles in a radical state. In addition, the term “ions corresponding to a gas” may be ions when gaseous particles of the gas are ionized by receiving high energy and converted into ionized particles.

For example, “radicals corresponding to an oxygen (O₂) gas” may be “oxygen radicals (O⁻). In addition, “ions corresponding to the oxygen (O₂) gas” may be “oxygen ions (O⁺).

The main chamber 100 may be implemented as various types of plasma chambers such as a capacitively coupled plasma (CCP) chamber, an inductively coupled plasma (ICP) chamber, a microwave plasma chamber, etc., according to the type of the second plasma ignition apparatus 402.

According to an embodiment, as shown in FIG. 1, when the second plasma ignition apparatus 402 is implemented to include a plurality of coils surrounding the main chamber 100 and a radio frequency (RF) power source that applies RF power to the plurality of coils, the main chamber 100 may be an ICP chamber.

According to an embodiment, when the second plasma ignition apparatus 402 is implemented as an RF power source that applies RF power to the shower head 110 and/or the electrostatic chuck 130, a plasma may be generated by a potential difference between the shower head 110 and the electrostatic chuck 130, and the main chamber 100 may be a CCP chamber.

The shower head 110 may be disposed at the top of the main chamber 100. The shower head 110 may be fixed to an upper sidewall of the main chamber 100. The shower head 110 may supply gas and/or radicals into the main chamber 100. In addition, the shower head 110 may include a cooling means (e.g., a cooler) and/or a heating means (e.g., a heater). The cooling means may discharge heat transferred to the shower head 110 to the outside, and the heating means may heat the shower head 110 to prevent the temperature of the shower head 110 from being lowered below a temperature required for generating and maintaining a plasma.

The shower head 110 may be implemented in a cylindrical shape having a relatively large radius compared to its height. In addition, the shower head 110 may include a plurality of first holes 111 and a plurality of second holes 112. Here, the plurality of first holes 111 provide a path through which first radicals may move from the upper plasma chamber 200 into the main chamber 100. The plurality of second holes 112 provide a path through which a gas supplied from the second gas supply pipe 302 to the shower head 110 may move into the main chamber 100.

The plurality of first holes 111 may be holes penetrating the shower head 110 in a vertical direction from an upper surface of the shower head 110 to a lower surface of the shower head 110, and the plurality of second holes 112 may be holes penetrating/extending in the vertical direction from a middle of the shower head 110 to the lower surface of the shower head 110. Here, the middle of the shower head 110 may be a level at a middle height between the upper surface and the lower surface of the shower head 110. For example, when the height of the shower head 110 in the cylindrical shape is ‘H’, the middle (e.g., a middle level) of the shower head 110 may be on a plane at a position which is ‘H/2’ away from the lower surface of the shower head 110 in the vertical direction.

The ion-blocking structure 120 may be disposed between the upper plasma chamber 200 and the main chamber 100, and allow the movement of radicals from the upper plasma chamber 200 toward the main chamber 100 but may block the movement of ions. For example, the ion-blocking structure 120 may be an ion-blocker having a circular plate shape and formed of or including a conductive material, e.g., a conductive metal. In addition, a lower surface of the ion-blocking structure 120 may contact the upper surface of the shower head 110, and the ion-blocking structure 120 may be coupled to the shower head 110. The ion-blocking structure 120 and the shower head 110 may be coupled to each other through various physical methods such as a screw tightening method, an adhesive method, a pin coupling method, a welding method, etc.

According to an embodiment, the ion-blocking structure 120 may be a structure in the cylindrical shape that generates an electric field. For example, the ion-blocking structure 120 may be electrically connected to a power source that applies a positive potential to the ion-blocking structure 120 so that the positive potential may be applied to the ion-blocking structure 120, and a ground potential or a negative potential may be applied to a wall surface constituting the upper plasma chamber 200. In this case, due to an electric field formed between the ion-blocking structure 120 and the wall surface of the upper plasma chamber 200, positively charged ions may be accelerated in the opposite direction of a direction toward the ion-blocking structure 120. For example, positive ions in the upper plasma chamber 200 may move in the same direction as the electric field formed between the ion-blocking structure 120 and the wall surface of the upper plasma chamber 200, e.g., in a direction receding from the ion-blocking structure 120. Therefore, ions may not move through the ion-blocking structure 120. On the other hand, radicals that are not positively charged and negatively charged may pass through the ion-blocking structure 120 and move into the main chamber 100 without being affected by the electric field formed between the ion-blocking structure 120 and the wall surface of the upper plasma chamber 200. For example, the radicals may be electrically neutral.

According to an embodiment, the ion-blocking structure 120 may be a structure in the cylindrical shape including a plurality of through holes. Here, the plurality of through holes may be holes in the cylindrical shape. Here, upper plasma formed in an upper plasma formation space UPS may include radicals and ions. While radicals may pass through the plurality of through holes and move into the main chamber 100, ions may collide with the ion-blocking structure 120 while passing through the plurality of through holes and be captured by the ion-blocking structure 120 due to the collision. The plurality of through holes may have a cylindrical shape, and the larger the diameter of the plurality of through holes, the lower the number of collisions between the ions and the ion-blocking structure 120, which may increase the possibility that the ions may flow into the main chamber 100. Therefore, the diameter of the plurality of through holes may be set to be small enough to capture all ions flowing into the plurality of through holes.

In the above description, the diameter of the plurality of through holes may be set to be small enough to “capture all ions,” but the expression “capture all ions” means “capture substantially all ions.” For example, the term “capture all ions” may mean that the ion-blocking structure 120 captures about 95%, about 96%, about 97%, or about 99% of the ions flowing into the plurality of through holes.

In the above description, the ion-blocking structure 120 is described separately as the “structure in the cylindrical shape that generates the electric field” and as the “structure in the cylindrical shape including the plurality of through holes”, but this is only for convenience of explanation, and the ion-blocking structure 120 may be the structure in the cylindrical shape, which is connected to a direct current (DC) or RF power source, receives a certain potential, generates the electric field, and simultaneously includes the plurality of through holes. In addition, the shape of the ion-blocking structure 120 is not limited to the structure in the cylindrical shape, but may have a shape corresponding to (e.g., the same as) the shape of the shower head 110. For example, when a bottom surface of the shower head 110 is rectangular, the ion-blocking structure 120 may also be implemented as a structure having a rectangular bottom surface. For example, the shower head 110 and the ion-blocking structure 120 may have the same area as each other in a plan view.

The electrostatic chuck 130 may be disposed at the bottom of the main chamber 100, and a wafer WF may be disposed and fixed on an upper surface of the electrostatic chuck 130. The electrostatic chuck 130 may fix the wafer WF by an electrostatic force. The electrostatic chuck 130 may include an electrode for chucking and dechucking the wafer WF therein, and may receive RF power from the bias power source 403.

The RF power provided from the bias power source 403 may allow a bias potential to be applied to the wafer WF. Here, the bias potential applied to the wafer WF may be a self-bias. When a negative bias potential is applied to the wafer WF, an electric field that attracts ions in a direction toward the wafer WF may be formed. Therefore, an anisotropic etching process or a deposition process based on (using) ions may be effectively performed on the wafer WF by the bias potential applied to the wafer WF. In this regard, the bias power source 403 may adjust the magnitude of the bias potential applied to the wafer WF by controlling the frequency and amplitude value of the RF power provided by the bias power source 403.

The upper plasma chamber 200 may be disposed at the top of the main chamber 100. In addition, the upper plasma chamber 200 may receive gas from a first gas supply pipe 301. The upper plasma chamber 200 may have an inner space having a certain size and may include a material having excellent wear resistance and corrosion resistance. For example, the upper plasma chamber 200 may include an aluminum block. For example, the upper plasma chamber 200 may include an upper chamber housing enclosing an upper plasma formation space UPS, and the upper chamber housing may be formed of aluminum.

The upper plasma chamber 200 may limit/define the upper plasma formation space UPS. In addition, as shown in FIG. 1, the upper plasma chamber 200 may be implemented in the form of combining two cylinders with different radii. The upper plasma chamber 200 may be in the form of a cylinder having a diameter of ‘D1’ at the top, but may be in the form of a cylinder having a diameter of ‘D2’ at the bottom. However, the upper plasma chamber 200 may be implemented in various shapes, such as in the shape of a cylinder having the same diameter at the top and bottom.

The upper plasma formation space UPS may be a space in which upper plasma is formed. Here, the upper plasma may be a plasma generated by discharging gas supplied from the first gas supply pipe 301 by the first plasma ignition apparatus 401. The upper plasma may include first radicals and first ions corresponding to the gas supplied from the first gas supply pipe 301.

In the present disclosure, the first radicals and the first ions may be radicals and ions generated in the upper plasma formation space UPS, respectively, and the first radicals may be supplied from the upper plasma formation space UPS into the main chamber 100. On the other hand, the second radicals and the second ions may be radicals and ions generated in the main plasma formation space MPS, respectively.

The upper plasma chamber 200 may be implemented as various types of plasma chambers such as a CCP chamber, an ICP chamber, a microwave plasma chamber, etc., according to the type of the first plasma ignition apparatus 401.

The main chamber 100 and the upper plasma chamber 200 are described as separate configurations in the above description, but the main chamber 100 and the upper plasma chamber 200 may be implemented by one housing. For example, the ALD apparatus 10 according to an embodiment may be configured by one housing surrounding both the upper plasma formation space UPS and the main plasma formation space MPS. In this case, the upper plasma formation space UPS and the main plasma formation space MPS may be divided by the shower head 110 and the ion-blocking structure 120.

The gas supply source 300 may supply gas from the outside of the main chamber 100 and the upper plasma chamber 200 to the first gas supply pipe 301 and/or the second gas supply pipe 302. The first gas supply pipe 301 may be a pipe connecting the gas supply source 300 to the upper plasma chamber 200, and the second gas supply pipe 302 may be a pipe connecting the gas supply source 300 to the shower head 110. FIG. 1 illustrates only a structure in which the first gas supply pipe 301 is connected to an upper end of the upper plasma chamber 200, but this is only an example and the first gas supply pipe 301 may be connected to a side surface and/or a lower surface of the upper plasma chamber 200.

The gas supply source 300 may include a gas flow controller to adjust the amount of gas supplied to the first gas supply pipe 301 and/or the second gas supply pipe 302. For example, the gas flow controller may include or may be a mass flow controller.

According to an embodiment, in order to supply more inhibitor gas to the upper plasma chamber 200, the mass flow controller included in the gas supply source 300 may control the mass flow of the inhibitor gas supplied to the first gas supply pipe 301 to be higher than the mass flow of the inhibitor gas supplied to the second gas supply pipe 302.

The gas supply source 300 may include a plurality of storage chambers respectively storing various types of gases required for an ALD process. For example, the gas supply source 300 may include an inhibitor gas storage chamber, a reaction gas storage chamber, an etching gas storage chamber, a precursor gas storage chamber, and a purge gas storage chamber.

Here, the inhibitor gas storage chamber, the reaction gas storage chamber, and the etching gas storage chamber may be connected to both the first gas supply pipe 301 and the second gas supply pipe 302. Thus, the inhibitor gas, reaction gas, and etching gas may be supplied to the upper plasma chamber 200 through the first gas supply pipe 301 or to the main chamber 100 through the second gas supply pipe 302 according to a progress of the process. On the other hand, the precursor gas storage chamber and the purge gas storage chamber may be connected to the second gas supply pipe 302. Therefore, precursor gas and purge gas may only be supplied to the main chamber 100 through the second gas supply pipe 302 according to the progress of the process.

The first plasma ignition apparatus 401 and the second plasma ignition apparatus 402 are apparatuses that generate upper plasma and main plasma, respectively. As shown in FIG. 1, each of the first plasma ignition apparatus 401 and the second plasma ignition apparatus 402 may be an apparatus capable of generating an ICP inside a chamber. In this case, each of the first plasma ignition apparatus 401 and the second plasma ignition apparatus 402 may be implemented with a plurality of coils surrounding the chamber and an RF power source providing RF power to the plurality of coils.

However, it is only an example that each of the first plasma ignition apparatus 401 and the second plasma ignition apparatus 402 may be implemented as a plasma ignition apparatus capable of generating an ICP, and each may be implemented as a plasma ignition apparatus capable of generating various types of plasma such as a CCP and a microwave plasma.

The controller 410 may control the overall operations of the ALD apparatus 10. For example, the controller 410 may be operatively connected to the gas supply source 300, the first plasma ignition apparatus 401, the second plasma ignition apparatus 402, and the bias power source 403. The controller 410 may include at least one of a microprocessor, a digital signal processor, or a processing apparatus similar thereto.

According to an embodiment, the controller 410 may control at least one of the gas supply source 300, the first plasma ignition apparatus 401, the second plasma ignition apparatus 402, and/or the bias power source 403 according to a selected mode.

For example, the controller 410 may control the gas supply source 300 to supply the inhibitor gas to the first gas supply pipe 301 in an inhibitor adsorption mode for filling a bottom gap of a trench, control the gas supply source 300 to supply the precursor gas to the second gas supply pipe 302 in a precursor adsorption mode for filling the bottom gap, and control the gas supply source 300 to supply the reactive gas to the first gas supply pipe 301 in an atomic layer formation mode for filling the bottom gap. The bottom gap of a trench described in the present disclosure may be a bottom portion of a trench formed on a wafer WF.

As another example, the controller 410 may control the gas supply source 300 to supply the inhibitor gas to the first gas supply pipe 301 and the second gas supply pipe 302 and control the second plasma ignition apparatus 402 to generate the main plasma in the inhibitor adsorption mode for filling a top gap of the trench. In addition, the controller 410 may control the gas supply source 300 to supply the precursor gas to the second gas supply pipe 302 in the precursor adsorption mode for filling the top gap. In the atomic layer formation mode for filling the top gap, the controller 410 may control the gas supply source 300 to supply the reaction gas to the first gas supply pipe 301 and the second gas supply pipe 302 and control the second plasma ignition apparatus 302 to generate the main plasma. The top gap of a trench described in the present disclosure may be a top portion or an upper portion of a trench formed on a wafer WF.

The above-described example is only one example in which the controller 410 may control the gas supply source 300 and/or the first plasma ignition apparatus 401 according to modes, and the controller 410 may transmit various control signals for various configurations so that the ALD apparatus 10 performs various processes.

In the following description, “the gas supply source 300, the first plasma ignition apparatus 401, the second plasma ignition apparatus 402, and the bias power source 403” may be described as respective operation subjects. However, this is for convenience of explanation, and all operations performed by the gas supply source 300, the first plasma ignition apparatus 401, the second plasma ignition apparatus 402, and the bias power source 403 may be performed based on control signals received from the controller 410.

The ALD apparatus 10 according to an embodiment of the inventive concept may perform various processes by selectively combining various types of particles such as ‘a process using the first radicals’, ‘a process using the second radicals and the second ions’, ‘a process using the first radicals, the second radicals and the second ions’, and ‘a process using the first radicals and a gas’. As a result, the ALD apparatus 10 according to an embodiment of the inventive concept may select necessary particles according to the progress of the process and use the selected particles in the ALD process, thereby achieving the effect of uniformly filling the gap of the trench present in the wafer WF. In the present disclosure, a gap of a trench may be a space between opposite sidewalls of the trench.

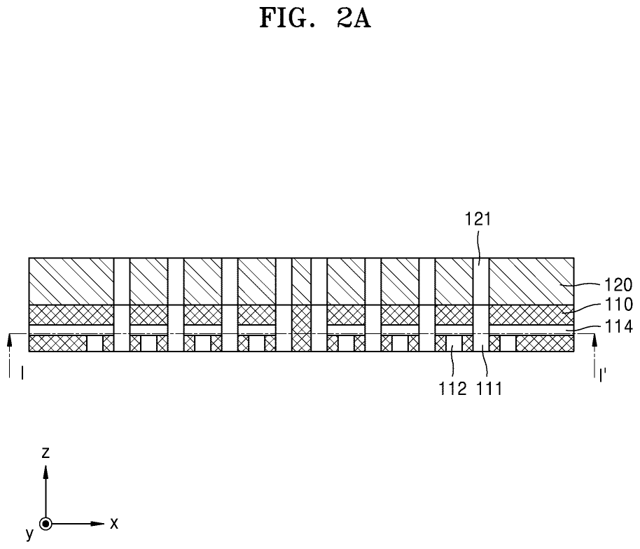

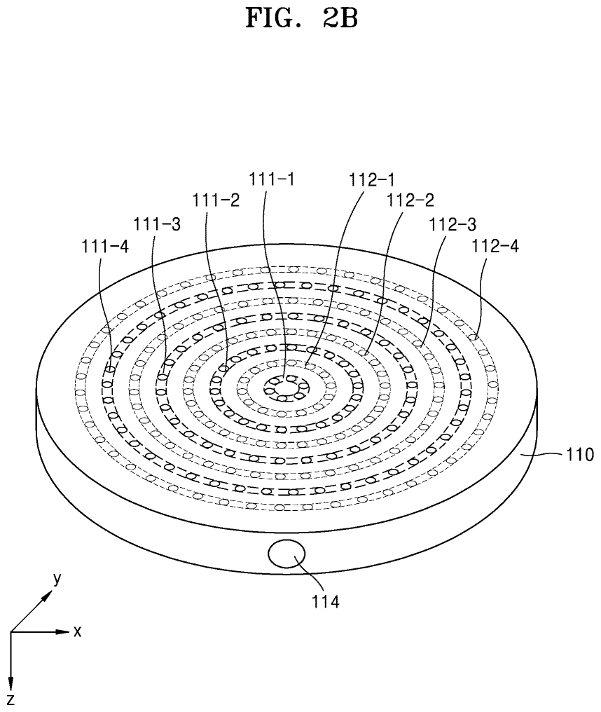

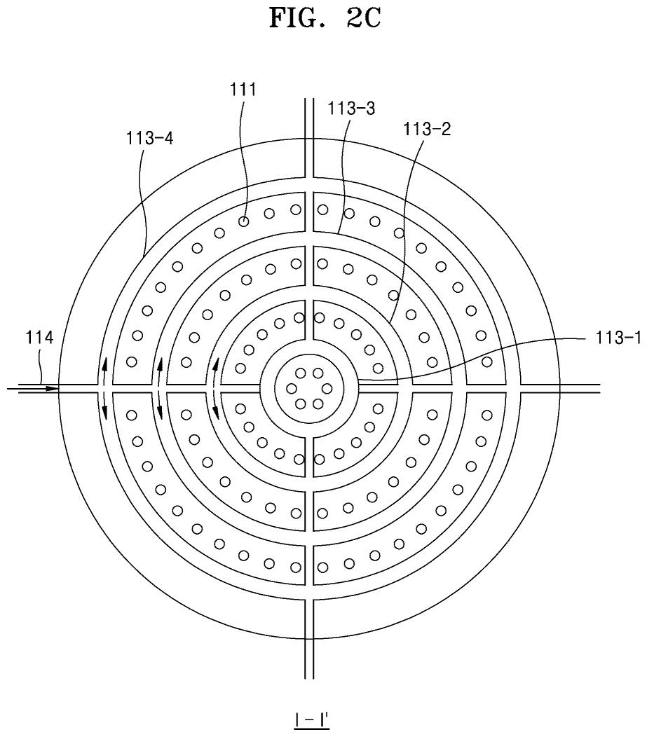

The above-described effect is mainly due to the fact that the shower head 110 and the ion-blocking structure 120 may independently supply the first radicals and the gas into the main chamber 100, and thus, the structures of the shower head 110 and the ion-blocking structure 120 are described in detail with reference to FIGS. 2A, 2B and 2C.

FIG. 2A is a cross-sectional diagram for describing the shower head 110 and the ion-blocking structure 120 according to an embodiment, FIG. 2B is a perspective view of the shower head 110 according to an embodiment, and FIG. 2C is a cross-sectional view of the shower head 110 according to an embodiment.

Referring to FIG. 2A, the shower head 110 may include the plurality of first holes 111 and the plurality of second holes 112, and the ion-blocking structure 120 may include a plurality of through holes 121. The plurality of through holes 121 may be holes penetrating the ion-blocking structure 120 from an upper surface to a lower surface of the ion-blocking structure 120 in a vertical direction.

The plurality of through holes 121 may be respectively connected to the plurality of first holes 111. Therefore, first radicals that respectively have passed through the plurality of through holes 121 may flow into the plurality of first holes 111, and pass through the plurality of first holes 111 to move into the main chamber 100.

According to an embodiment, a central axis of each of the plurality of through holes 121 may be the same as a central axis of a corresponding one of the plurality of first holes 111. For example, the plurality of through holes 121 and the plurality of first holes 111 may be cylindrical holes having the same central axes with corresponding counterparts.

According to an embodiment, as shown in FIG. 2A, the width of each of the plurality of through holes 121 may be the same as the width of a corresponding one of the plurality of first holes 111. When an upper surface of the shower head 110 and a lower surface of the ion-blocking structure 120 contact each other, the first hole 111 connected to a corresponding one of the plurality of through holes 121 may form one vertical flow path with the corresponding one through hole 121 coupled together.

FIG. 2A illustrates that the width of each of the plurality of through holes 121 is the same as the width of a corresponding one of the plurality of first holes 111, but this is only an example, and the plurality of through holes 121 may be implemented in various structures and shapes that may be respectively connected to the plurality of first holes 111, e.g., the width of each of the plurality of first holes 111 being greater than the width of the corresponding one of the plurality of through holes 121.

Referring to FIG. 2B, the plurality of first holes 111 and the plurality of second holes 112 may be arranged alternately with each other. FIG. 2B is a perspective view of a lower surface of the shower head 110.

According to an embodiment, the plurality of first holes 111 and the plurality of second holes 112 may be arranged alternately with each other in a radial direction from the center of the shower head 110. For example, when the first holes 111 are at a position separated by ‘R₁’ in a radial direction from the center of the shower head 110, the second holes 112 may be at a position separated by ‘R₂’ in the radial direction, the first holes 111 may be again at a position separated by ‘2R₁’ in the radial direction, and the second holes 112 may be again at a position separated by ‘2R₂’ (R₂>R₁). In certain embodiments, when the first holes 111 are formed at positions having distances R, 3R, 5R, etc. in a radial direction from the center of the shower head 110, e.g., in a plan view, the second holes 112 may be formed at positions having distances 2R, 4R, 6R, etc. in the radial direction from the center of the shower head 110, e.g., in the plan view.

As described above, the first holes 111 and the second holes 112 may be arranged alternately with each other whenever separated from each other by an equal distance in the radial direction, but this is only an example. The plurality of first holes 111 and the plurality of second holes 112 may be arranged alternately with each other according to various methods, such as the first holes 111 and the second holes 112 may be arranged alternately with each other whenever separated from each other by different distances.

According to an embodiment, the plurality of second holes 112 may be grouped into first to nth groups according to a distance spaced apart from the center of the shower head 110 in the radial direction. For example, the second holes 112 at positons spaced apart by ‘R₂’ or ‘2R’ in the radial direction from the center of the shower head 110 may be grouped into second holes 112-1 of the first group, the second holes 112 at positons spaced apart by ‘2R₂’ or ‘4R’ may be grouped into second holes 112-2 of the second group, the second holes 112 at positons spaced apart by ‘3R₂’ or ‘6R’ may be grouped into second holes 112-3 of the third group, and the second holes 112 at positons spaced apart by ‘4R₂’ or ‘8R’ may be grouped into second holes 112-4 of the fourth group.

Here, the plurality of first holes 111 may be disposed between positions of two adjacent groups among the first to nth groups. For example, the plurality of first holes 111 may be disposed between positions of second holes 112-1 and second holes 112-2, between positions of second holes 112-2 and second holes 112-3, between positions of second holes 112-3 and second holes 112-4.

According to an embodiment, the plurality of first holes 111 may also be grouped into first to nth groups according to the distance spaced apart from the center of the shower head 110 in the radial direction. For example, the first holes 111 at positons spaced apart by ‘R₁’ or ‘R’ in the radial direction from the center of the shower head 110 may be grouped into first holes 111-1 of the first group, the first holes 111 at positons spaced apart by ‘2R₁’ or ‘3R’ may be grouped into first holes 111-2 of the second group, the first holes 111 at positons spaced apart by ‘3R₁’ or ‘5R’ may be grouped into first holes 111-3 of the third group, and the first holes 111 at positons spaced apart by ‘4R₁’ or ‘7R’ may be grouped into first holes 111-4 of the fourth group.

Because the plurality of second holes 112 need to receive gas from the second gas supply pipe 302, the plurality of second holes 112 may be connected to a plurality of flow paths and gas inlet holes existing inside the shower head 110. This will be described in detail with reference to FIG. 2C.

FIG. 2C is a cross-sectional view taken along line I-I′ of FIG. 2A. For example, FIG. 2C is a cross-sectional view taken along a plane parallel to the upper surface of the shower head 110 and taken along the middle of the shower head 110.

Referring to FIG. 2C, the shower head 110 may include a gas inlet hole 114 in a side surface thereof. The gas inlet hole 114 may be connected to the second gas supply pipe 302, and may supply gas supplied from the second gas supply pipe 302 into the shower head 110. When the ALD apparatus 10 includes one second gas supply pipe 302, the shower head 110 may include one gas inlet hole 114, and when the ALD apparatus 10 includes a plurality of second gas supply pipes 302, a plurality of gas inlet holes 114 may be implemented in the shower head 110. For example, the number of the gas inlet holes 114 may correspond to the number of the second gas supply pipes 302.

According to an embodiment, when the ALD apparatus 10 includes four second gas supply pipes 302, the shower head may include four gas inlet holes 114 as shown in FIG. 2C. In this case, the four gas inlet holes 114 may be disposed at regular distances in a circumferential direction on the side surface of the shower head 110. For example, distances between adjacent gas inlet holes 114 may be the same in the circumferential direction.

When the ALD apparatus 10 includes N (e.g., a plural number) second gas supply pipes 302, the shower head 110 may include N gas inlet holes 114, and the N gas inlet holes 114 may be disposed at regular distances in the circumferential direction on the side surface of the shower head 110. For example, distances between adjacent gas inlet holes 114 may be the same along the circumferential direction on the side surface of the shower head 110.

A plurality of flow paths for uniformly supplying a gas to the plurality of second holes 112 may be formed at the middle level of the shower head 110. The plurality of flow paths may uniformly transmit the gas supplied from the second gas supply pipe 302 inside the shower head 110 toward the plurality of second holes 112.

According to an embodiment, the plurality of flow paths may include first to nth circular flow paths. Here, the first to nth circular flow paths may be at positions corresponding to positions of the second holes 112 of the first to nth groups.

As shown in FIG. 2C, a first circular flow path 113-1, a second circular flow path 113-2, a third circular flow path 113-3, and a fourth circular flow path 113-4 may be formed at the middle level of the shower head 110. The second holes 112-1 of the first group may be disposed on a lower surface of the first circular flow path 113-1, the second holes 112-2 of the second group may be disposed on a lower surface of the second circular flow path 113-2, the second holes 112-3 of the third group may be disposed on a lower surface of the third circular flow path 113-3, and the second holes 112-4 of the fourth group may be disposed on a lower surface of the fourth circular flow path 113-4.

The gas supplied to the first to fourth circular flow paths 113-1, 113-2, 113-3, and 113-4 through the gas inlet hole 114 diffuses in the circumferential direction in each circular flow path. In this regard, the second holes 112-1, 112-2, 112-3, and 112-4 of the first to fourth groups are respectively disposed in the lower surfaces of the first to fourth circular flow paths 113-1, 113-2, 113-3, and 113-4, and thus, the plurality of circular flow paths may uniformly supply the gas to the plurality of second holes 112.

Referring to FIGS. 2A and 2C, a supply direction of first radicals passing through the plurality of through holes 121 and flowing into the plurality of first holes 111 may be a vertical direction, while a supply direction of the gas flowing into the plurality of circular flow paths through the gas inlet hole 114 may be a horizontal direction. Because the supply directions of the first radicals and the gas supplied into the shower head 110 are different from each other, the shower head 110 may independently receive the first radicals and the gas from each other. As a result, the shower head 110 may independently supply the first radicals and the gas into the main chamber 100 without mixing the first radicals and the gas inside the shower head 110.

The ALD apparatus 10 according to an embodiment of the inventive concept includes the shower head 110 and the ion-blocking structure 120 as described above, thereby performing various types of processes using the first radicals and the gas. In the following description of embodiments with reference to the drawings, various types of processes that may be performed by the ALD apparatus 10 according to embodiments of the inventive concept are described in detail.

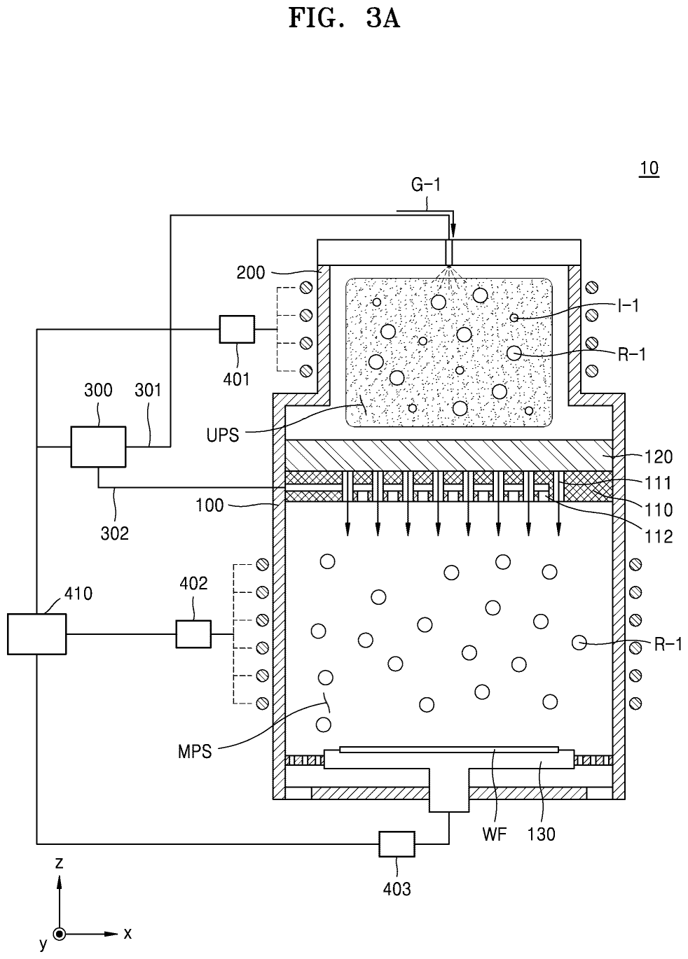

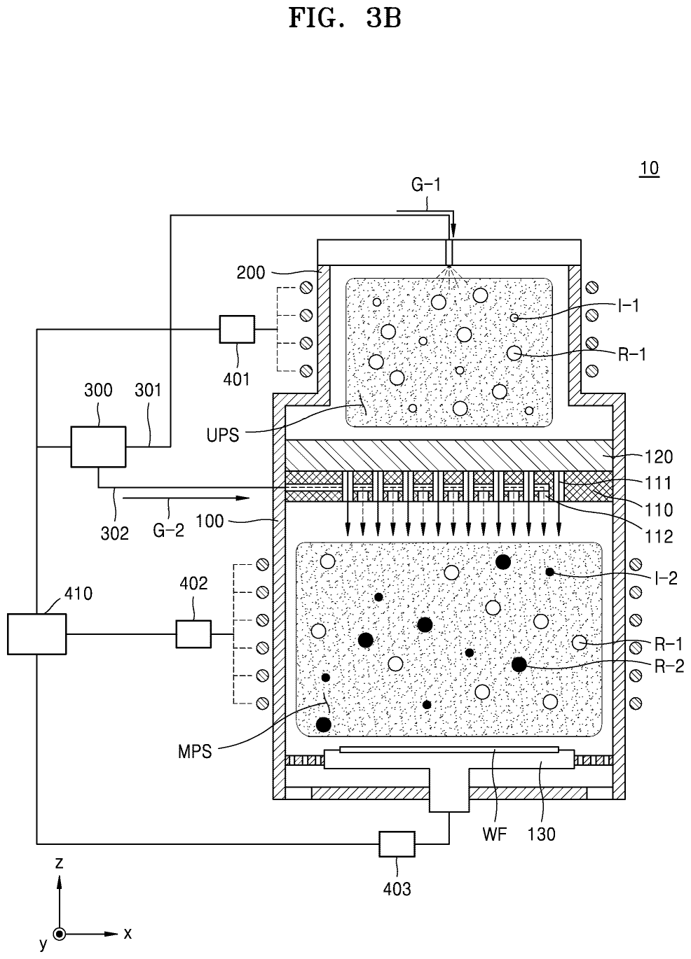

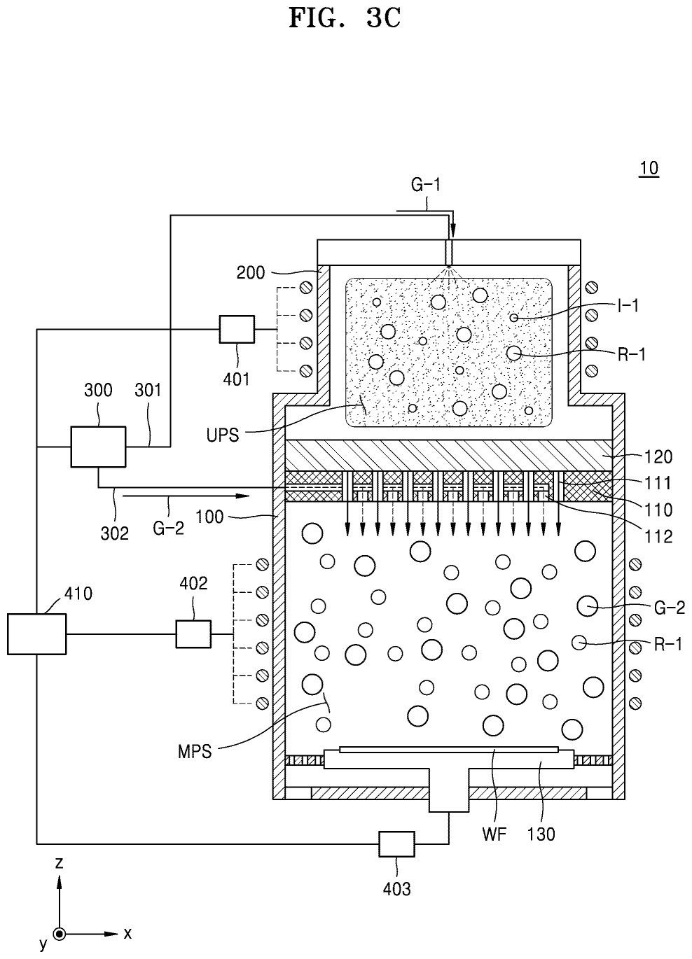

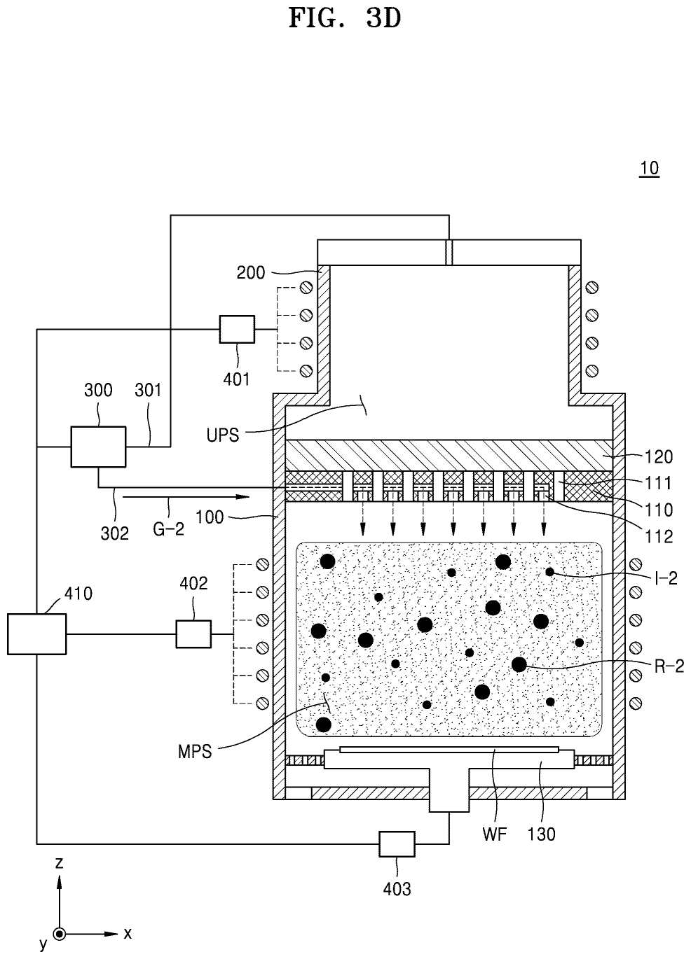

FIG. 3A is a cross-sectional diagram for describing a process of the ALD apparatus 10 using first radicals R-1 according to an embodiment.

According to an embodiment, the ALD apparatus 10 may perform an inhibitor adsorption process for filling a bottom gap of a trench by using the first radicals. Here, the “inhibitor adsorption process for filling the bottom gap” may be a process performed when the ALD apparatus 10 operates in an “inhibitor adsorption mode for filling the bottom gap”. For example, the “inhibitor adsorption process for filling the bottom gap” may be a process of adsorbing an inhibitor material on a sidewall of a top gap of the trench by exposing the side wall of the top gap to radicals corresponding to an inhibitor gas for a certain period of time.

The inhibitor material may be a material that does not react with a precursor material and a reaction material, and may be used to selectively deposit a precursor gas and a reaction gas only on a specific region of the wafer WF. For example, in a silicon dioxide (SiO₂) ALD process, the inhibitor gas may be a gas including nitrogen components (e.g., N₂ gas, NH₃ gas, and NF₃ gas).

Radicals corresponding to the inhibitor gas may have better reactivity with the wafer WF than the inhibitor gas. Therefore, the ALD apparatus 10 may perform the inhibitor adsorption process based on the radicals corresponding to the inhibitor gas, thereby performing the process at a faster speed and accurately adsorbing the inhibitor to a region where a user wants to adsorb the inhibitor.

For example, a method in which the ALD apparatus 10 performs the inhibitor adsorption process using a radical inhibitor is as follows.

The gas supply source 300 may supply a first gas G-1 to the first gas supply pipe 301. Here, the first gas G-1 is an inhibitor gas, and the supply of the first gas G-1 may be performed in a pulse form. For example, the gas supply source 300 may supply the first gas G-1 at a preset flow rate for a preset time interval. For example, the gas supply source 300 may supply N₂ gas at a mass flow rate of 100 mg/s for 3 seconds.

Here, the preset flow rate and the preset time interval may be determined based on the area and position of a region to which the inhibitor material is to be adsorbed. For example, when the inhibitor is to be adsorbed only to the uppermost end of the trench of the wafer WF, the inhibitor gas may be supplied at a small flow rate for a short time interval, whereas when the inhibitor is to be adsorbed to a bottom end of the trench of the wafer WF, the inhibitor gas having a relatively large flow rate may be supplied for a relatively long time interval. The flow rate and time adjustment as described above may be performed through a flow controller included in the gas supply source 300.

The first plasma ignition apparatus 401 may generate upper plasma in the upper plasma formation space UPS. Here, the upper plasma is a plasma formed by discharging the first gas G-1, and may include radicals and ions corresponding to the first gas G-1. For example, the first plasma ignition apparatus 401 may include a plurality of coils surrounding the upper plasma chamber 200 and an RF power source supplying RF power to the plurality of coils. In this case, when the supply of the first gas G-1 is performed, the RF power source may generate the upper plasma by supplying RF power of a preset frequency to the plurality of coils. Here, the preset frequency may be set to various values for plasma generation, such as 13.56 MHz and 2.45 GHz.

The upper plasma may include the first radicals R-1 and first ions I-1. The first ions I-1 may be captured by the ion-blocking structure 120, but the first radicals R-1 may be supplied into the main chamber 100 through the ion-blocking structure 120 and the shower head 110. The first radicals R-1 may move in a direction approaching the wafer WF by gravity inside the main chamber 100 and be adsorbed to the wafer WF. Here, because the first radicals R-1 are radicals corresponding to the inhibitor gas, an adsorbed inhibitor layer may be formed on an upper sidewall of the trench of the wafer WF. For example, the adsorbed inhibitor layer may be formed on the surface of the wafer WF and the upper sidewall of the trench. Because the precursor gas and the reaction gas do not adsorb and/or react to a region where the inhibitor layer is formed, the precursor gas and the reaction gas may selectively adsorb and/or react only to a region where the inhibitor layer is not formed.

According to an embodiment, the ALD apparatus 10 may perform an atomic layer forming process for filling the bottom gap of the trench by using the first radicals. Here, the “atomic layer forming process for filling the bottom gap” may be a process performed when the ALD apparatus 10 operates in an “atomic layer forming mode for filling the bottom gap”. For example, the “atomic layer forming process for filling the bottom gap” may be a process of forming an atomic layer in the bottom gap of the trench by reacting radicals corresponding to a reaction gas with a precursor layer formed in the bottom gap.

The reaction material is a material that reacts with a precursor material to form an atomic layer, and may react with a precursor material selectively adsorbed to only a specific region of the wafer WF to form the atomic layer. For example, in a silicon dioxide (SiO₂) ALD process, the reaction gas may be a gas including an oxygen component (e.g., O₂ gas and N₂O gas).

Radicals corresponding to the reaction gas have better/higher reactivity with the precursor material than the reaction gases. Therefore, the ALD apparatus 10 may perform the atomic layer forming process based on (e.g., using) the radicals corresponding to the reaction gas, thereby forming the atomic layer at a faster speed.

A method in which the ALD apparatus 10 performs the atomic layer forming process using the radicals corresponding to the reaction gas is the same or substantially the same as the method of performing the inhibitor adsorption process described above, and thus a brief description will be given about the atomic layer forming process.

The gas supply source 300 may supply the first gas G-1 to the first gas supply pipe 301 in a pulse form. For example, the gas supply source 300 may supply the first gas G-1 at a preset flow rate for a preset time interval to the first gas supply pipe 301. In addition, the first plasma ignition apparatus 401 may generate upper plasma in the upper plasma formation space UPS. The upper plasma may include the first radicals R-1 and the first ions I-1. The first ions I-1 may be captured by the ion-blocking structure 120, but the first radicals R-1 may be supplied into the main chamber 100 through the ion-blocking structure 120 and the shower head 110. Here, because the first radicals R-1 are radicals corresponding to the reaction gas, reaction gas radicals may react with the precursor layer formed in the bottom gap of the trench to form an atomic layer.

As described above, the ALD apparatus 10 may perform the inhibitor adsorption process and the atomic layer forming process for filling the bottom gap of the trench by using only the first radicals R-1. However, this is only an example of two representative processes using only the first radicals R-1, and the ALD apparatus 10 may perform various types of processes using only the first radicals R-1.

FIG. 3B is a cross-sectional diagram for describing a process of the ALD apparatus 10 using the first radicals R-1, second radicals R-2, and second ions I-2 according to an embodiment.

According to an embodiment, the ALD apparatus 10 may perform an inhibitor adsorption process for filling a top gap of a trench by using the first radicals R-1, the second radicals R-2, and the second ions I-2.

Here, the “inhibitor adsorption process for filling the top gap” may be a process performed when the ALD apparatus 10 operates in an “inhibitor adsorption mode for filling the top gap”. For example, the “inhibitor adsorption process for filling the top gap” may be a process of adsorbing an inhibitor material to the uppermost end of the trench by exposing the uppermost end to radicals and ions corresponding to an inhibitor gas for a certain period of time.

A specific method in which the ALD apparatus 10 performs the inhibitor adsorption process for filling the top gap of the trench using the first radicals R-1, the second radicals R-2, and the second ions I-2 is as follows.

The gas supply source 300 may supply the first gas G-1 to the first gas supply pipe 301 and supply a second gas G-2 to the second gas supply pipe 302. Here, the first gas G-1 and the second gas G-2 are inhibitor gases, and the supply of the first gas G-1 and the second gas G-2 may be performed in a pulse form. For example, the gas supply source 300 may supply the first gas G-1 and the second gas G-2 at a preset flow rate for a preset time interval. For example, the gas supply source 300 may supply a N₂ gas at a mass flow rate of 50 mg/s for 2 seconds.

The first plasma ignition apparatus 401 may generate upper plasma in the upper plasma formation space UPS, and the second plasma ignition apparatus 402 may generate main plasma in the main plasma formation space MPS. Here, the main plasma is a plasma formed by discharging the second gas G-2, and may include the second radicals R-2 and the second ions I-2 corresponding to the second gas G-2. In the inhibitor adsorption process for filling the top gap of the trench, because both the first gas G-1 and the second gas G-2 are inhibitor gases, the first radicals R-1, the first ions I-1, the second radicals R-2, and the second ions I-2 may all be radicals and ions corresponding to the inhibitor gas.

Here, the first ions I-1 may be captured by the ion-blocking structure 120, but the first radicals R-1 may be supplied into the main chamber 100. Therefore, the first radicals R-1, the second radicals R-2, and the second ions I-2 may be present inside the main chamber 100.

The first radicals R-1, the second radicals R-2, and the second ions I-2 may form an inhibitor layer on the uppermost end of the trench of the wafer WF. For example, the second ions I-2 may collide with the uppermost end of the trench to activate a collided region, and the region activated by the collision of the second ions I-2 may react actively with the first radicals R-1 and the second radicals R-2. As a result, the first radicals R-1, the second radicals R-2, and the second ions I-2 may form the inhibitor layer at the uppermost end of the trench.

According to an embodiment, the ALD apparatus 10 may perform an atomic layer forming process for filling the top gap of the trench by using the first radicals R-1, the second radicals R-2, and the second ions I-2.

Here, the “atomic layer forming process for filling the top gap” may be a process performed when the ALD apparatus 10 operates in an “atomic layer forming mode for filling the top gap”. For example, the “atomic layer forming process for filling the top gap” may be a process of forming an atomic layer on the top gap of the trench by reacting radicals and ions corresponding to a reaction gas with a precursor layer formed in the top gap.

A method in which the ALD apparatus 10 performs the atomic layer forming process in the top gap of the trench by using the first radicals R-1, the second radicals R-2, and the second ions I-2 is the same or substantially the same as the method of performing the inhibitor adsorption process described above, and thus a brief description will be given about the atomic layer forming process.

The gas supply source 300 may supply the first gas G-1 to the first gas supply pipe 301 and supply the second gas G-2 to the second gas supply pipe 302. Here, the first gas G-1 and the second gas G-2 are reaction gases, and the supply of the first gas G-1 and the second gas G-2 may be performed in a pulse form. For example, the gas supply source 300 may supply the first gas G-1 to the first gas supply pipe 301 and the second gas G-2 to the second gas supply pipe 302 at preset flow rates for preset time intervals, respectively. The first plasma ignition apparatus 401 may generate upper plasma in the upper plasma formation space UPS, and the second plasma ignition apparatus 402 may generate main plasma in the main plasma formation space MPS. In the atomic layer forming process for filling the top gap of the trench, because the first gas G-1 and the second gas G-2 are both reactive gases, the first radicals R-1, the first ions I-1, the second radicals R-2, and the second ions I-2 may all be radicals and ions corresponding to the reactive gas.

Here, the first ions I-1 may be captured by the ion-blocking structure 120, but the first radicals R-1 may be supplied into the main chamber 100. Therefore, the first radicals R-1, the second radicals R-2, and the second ions I-2 may be present inside the main chamber 100. The first radicals R-1, the second radicals R-2, and the second ions I-2 may react with a precursor layer formed in the top gap of the trench of the wafer WF to form the atomic layer.

The inhibitor adsorption process and the atomic layer forming process for filling the top gap of the trench may be different from the inhibitor adsorption process and the atomic layer forming process for filling the bottom gap of the trench, especially in that “the second ions I-2 is used” in the inhibitor adsorption process and the atomic layer forming process for filling the top gap of the trench.

Based on such a difference, the ALD apparatus 10 may prevent occurrence of a difference between the density of the atomic layer filling the bottom gap of the trench and the density of the atomic layer filling the top gap in a high aspect ratio trench structure. Charged particles such as ions or electrons are likely to collide with a sidewall of the trench and dissipate before moving to the lower surface of the trench in the high aspect ratio trench structure. Therefore, when the entire gap of the trench is filled using both ions and radicals without distinguishing between the process of filling the bottom gap and the process of filling the top gap of the trench, the density of the atomic layer may be high in the top gap with a high ion density, whereas the density of the atomic layer may be low in the bottom gap with a low ion density.

For example, the inhibitor layer needs to be adsorbed onto the upper sidewall in the inhibitor adsorption process for filling the bottom gap, and the inhibitor layer needs to be adsorbed onto the uppermost end sidewall in the inhibitor adsorption process for filling the top gap. For example, a position of the inhibitor layer adsorbed in the inhibitor adsorption process for filling the top gap is higher than a position of the inhibitor layer adsorbed in the inhibitor adsorption process for filling the bottom gap. By the same principle, in the atomic layer forming process for filling the bottom gap, an atomic layer needs to be formed through a reaction with a precursor layer formed on the bottom surface and sidewall of the lower surface of the trench, and in the atomic layer forming process for filling the top gap, an atomic layer needs to be formed through a reaction with a precursor layer formed on the upper surface of the trench. For example, a position of the atomic layer formed in the atomic layer forming process for filling the top gap is higher than a position of the atomic layer formed in the atomic layer forming process for filling the bottom gap.

The ALD apparatus 10 according to an embodiment of the inventive concept may adsorb and/or react materials faster by using ions capable of activating adsorption and/or reaction in a process of adsorbing and/or reacting materials on a sidewall at a relatively high position on a trench structure. In addition, the ALD apparatus 10 may adsorb and/or react materials by using radicals that may uniformly diffuse to a low position of a trench in the process of adsorbing and/or reacting materials on the sidewall or bottom surface at a relatively low position. As a result, the ALD apparatus 10 may fill the entire gap region of the trench with a uniform density.

In addition, the ALD apparatus 10 according to an embodiment may increase or decrease an ion ratio inside the main chamber 100 in/during a process.

In the present disclosure, “the ion ratio inside the main chamber 100” may be a ratio of the density of the second ions I-2 to a radical density inside the main chamber 100. In addition, the radical density may be a value obtained by summing the density of the first radicals R-1 and the density of the second radicals R-2.

According to an embodiment, the first plasma ignition apparatus 401 may reduce the ion ratio inside the main chamber 100 by increasing the RF power applied to the inside of the upper plasma chamber 200, and may increase the ion ratio inside the main chamber 100 by reducing the RF power applied to the inside of the upper plasma chamber 200. As the RF power applied to the inside of the upper plasma chamber 200 increases, the density of the upper plasma may increase. Accordingly, the density of the first radicals R-1 included in the upper plasma may increase, and the number of particles of the first radicals R-1 supplied into the main chamber 100 may increase. As the density of the first radicals R-1 increases, the ion ratio inside the main chamber 100 may decrease. On the contrary, when the RF power applied to the inside of the upper plasma chamber 200 decreases, the ion ratio inside the main chamber 100 may increase.

According to an embodiment, the second plasma ignition apparatus 402 may increase the ion ratio inside the main chamber 100 by increasing the RF power applied to the inside of the main chamber 100, and may reduce the ion ratio inside the main chamber 100 by reducing the RF power applied to the inside of the main chamber 100. As the RF power applied to the inside of the main chamber 100 increases, the density of the main plasma may increase. Accordingly, the number of particles of the second radicals R-2 and the second ions I-2 included in the main plasma may also increase. In this regard, when the number of particles of the first radicals R-1 is constant, the ion ratio inside the main chamber 100 may increase. On the contrary, when the RF power applied to the inside of the main chamber 100 decreases, the ion ratio inside the main chamber 100 may decrease.

According to an embodiment, the gas supply source 300 may increase the ion ratio inside the main chamber 100 by supplying the second gas G-2 at a flow rate higher than the flow rate of the first gas G-1, and may reduce the ion ratio inside the main chamber 100 by supplying the second gas G-2 at a flow rate lower than the flow rate of the first gas G-1. The upper plasma is a plasma generated by discharging the first gas G-1, and the main plasma is a plasma generated by discharging the second gas G-2. Therefore, when the flow rate of the first gas G-1 increases, the density of the first radicals R-1 increases, and when the flow rate of the first gas G-1 decreases, the density of the first radicals R-1 may decrease. In addition, when the flow rate of the second gas G-2 increases, the density of the second ions I-2 increases, and when the flow rate of the second gas G-2 decreases, the density of the second ions I-2 may decrease. As a result, the gas supply source 300 may increase or decrease the ion ratio inside the main chamber 100 by increasing or decreasing at least one of the flow rate of the first gas G-1 or the flow rate of the second gas G-2.

As described above, the ALD apparatus 10 may perform various processes for filling the top gap of the trench by using the first radicals R-1, the second radicals R-2, and the second ions I-2 present inside the main chamber 100, and may adjust the ion ratio inside the main chamber 100. In addition, the ALD apparatus 10 may also perform an etching process on an overhang by using the first radicals R-1, the second radicals R-2, and the second ions I-2 as necessary. A method in which the ALD apparatus 10 performs the etching process is described in detail with reference to the following drawings.

FIG. 3C is a cross-sectional diagram for describing a process of the ALD apparatus 10 using the first radicals R-1 and the second gas G-2 according to an embodiment.

According to an embodiment, the ALD apparatus 10 may perform a first etching process by using the first radicals R-1 and the second gas G-2.

Here, the first etching process is one of processes of etching an overhang formed in a gap of a trench by using the first radicals R-1 and the second gas G-2. For example, the first etching process may be an etching process performed based on a selective chemical reaction with an oxide. For example, the first etching process may be performed when the ALD apparatus 10 is set in a first etching mode, and performs the first etching mode. The first etching process is a process of selectively etching only an oxide by using a material which has a very high reactivity with the oxide (e.g., silicon dioxide (SiO₂)) to induce a chemical reaction, but has a very low chemical reactivity with materials other than the oxide to induce no reaction with the other materials.

To perform the first etching process, the gas supply source 300 may supply the first gas G-1 to the first gas supply pipe 301 and supply the second gas G-2 to the second gas supply pipe 302. Here, the first gas G-1 may be an etching gas, and the second gas G-2 may be an additional gas. The etching gas may be a highly reactive halogen-based gas (e.g., a F₂ gas or a SF₆ gas).

In addition, the additional gas may be a gas that performs a function of activating reaction between the etching gas and the oxide and suppressing reactions between the etching gas and other materials. For example, in the first etching process of etching the overhang including silicon dioxide (SiO₂), the additional gas may be a hydrogen gas H₂. However, the types of the etching gas and the additional gas described above are only examples, and the etching gas and the additional gas may be implemented as various types of gases according to the properties of a material to be etched.

The first plasma ignition apparatus 401 may generate upper plasma inside the upper plasma chamber 200. Here, since the first gas G-1 is an etching gas, the first radicals R-1 and the first ions I-1 may be radicals and ions corresponding to the etching gas.

The first radicals R-1 may be supplied into the main chamber 100, and the first radicals R-1 and the second gas G-2 may be present inside the main chamber 100. The first radicals R-1 and the second gas G-2 may be used in the first etching process of selectively etching an oxide.

FIG. 3D is a cross-sectional diagram for describing a process of the ALD apparatus 10 using the second radicals R-2 and the second ions I-2 according to an embodiment.

According to an embodiment, the ALD apparatus 10 may perform a second etching process by using the second radicals R-2 and the second ions I-2. Here, the second etching process is one of processes of etching the overhang formed in the gap of the trench by using the second radicals R-2 and the second ions I-2. For example, the second etching process may be performed when the ALD apparatus 10 is set in a second etching mode, and performs the second etching mode.

For example, the second etching process may be an etching process involving an ion collision. Here, the ion collision may be a phenomenon in which ions accelerated by an electric field (e.g., a plasma sheath electric field) collide with a surface of the wafer WF. For example, the second etching process may be a reactive ion etching (RIE) process.

To perform the second etching process, the gas supply source 300 may supply the second gas G-2 to the second gas supply pipe 302. Here, the second gas G-2 may be an etching gas. In addition, the second plasma ignition apparatus 402 may generate main plasma inside the main chamber 100. Here, because the second gas G-2 is the etching gas, the second radicals R-2 and the second ions I-2 may be radicals and ions corresponding to the etching gas. The second radicals R-2 and the second ions I-2 present inside the main chamber 100 may be used in the second etching process.

When the second etching process is performed, the bias power source 403 may apply a negative bias potential to the wafer WF. The second ions I-2 may be accelerated by the electric field formed by the bias potential applied to the wafer WF to collide with the wafer WF. Accordingly, the second etching process may be performed more quickly and more effectively.

The second etching process may have a better etching rate than the first etching process in which selective etching is performed using only particles of the first radicals R-1 and the second gas G-2. However, the first etching process has the advantage that a user may select and etch only a material (e.g., oxide) to be etched, and the second etching process may not be proper for a selective etching.

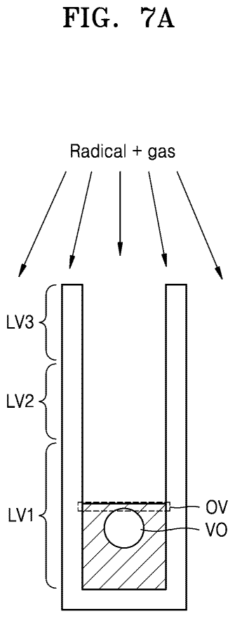

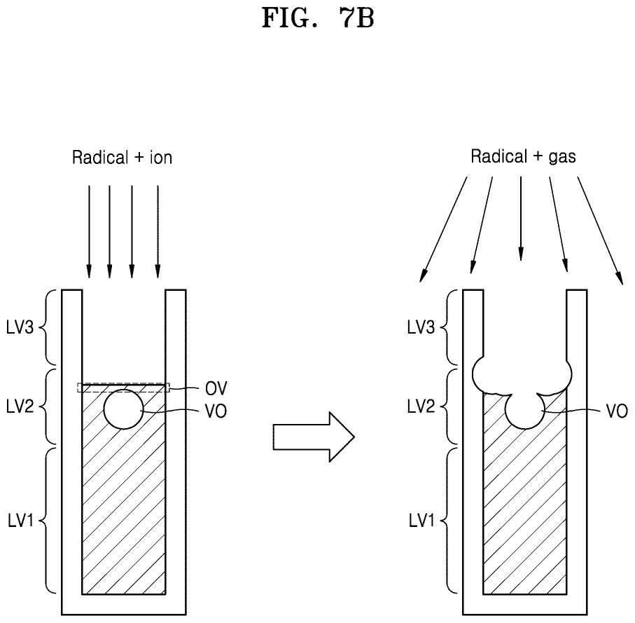

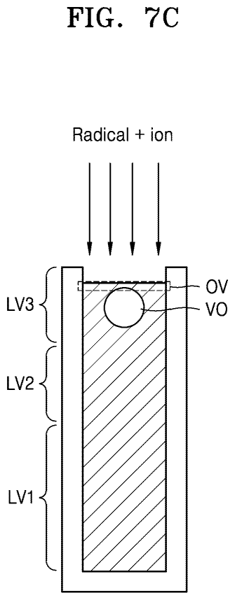

Therefore, the ALD apparatus 10 according to an embodiment of the inventive concept may identify which of the first etching process and the second etching process is suitable according to a position of the overhang to be etched, and select any one of the first etching process and the second etching process to perform etching on the overhang. The etching process selected according to the position of the overhang is described in detail with reference to FIGS. 7A to 7C below.

Although not described in detail above with reference to FIGS. 3A to 3D, the ALD apparatus 10 may perform a precursor adsorption process for filling the bottom gap and the top gap of the trench. Here, the precursor adsorption process for filling the bottom gap and the precursor adsorption process for filling the top gap may be respectively performed when the ALD apparatus 10 operates in “a precursor adsorption mode for filling the bottom gap” and “a precursor adsorption mode for filling the top gap”.

For example, to perform the precursor adsorption process, the gas supply source 300 may supply the second gas G-2 to the second gas supply pipe 302. Here, the second gas G-2 is a precursor gas, and the precursor gas is supplied to the second gas supply pipe 302 in a pulse form. For example, the gas supply source 300 may supply the second gas G-2 at a preset flow rate for a preset time interval to the second gas supply pipe 302. The precursor gas may be adsorbed to the bottom gap of the trench or the top gap of the trench to form a precursor layer.

As described above, the ALD apparatus 10 according to an embodiment may perform a gap filling process by dividing a gap of the trench into the bottom gap and the top gap. The gap filling process on the bottom gap and the top gap are described in detail with reference to the following drawings.

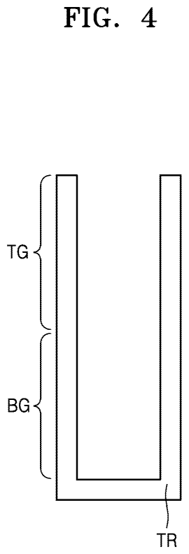

FIG. 4 is a cross-sectional diagram for describing a trench TR existing on a wafer according to an embodiment.

Referring to FIG. 4, a gap of the trench TR may include a bottom gap BG and a top gap TG. The ALD apparatus 10 may perform a top gap filling process after performing a bottom gap filling process. Here, the bottom gap filling process may be a process of depositing an atomic layer in the bottom gap BG of the trench TR, and the top gap filling process may be a process of depositing an atomic layer in the top gap TG of the trench TR.

The bottom gap filling process may include an inhibitor adsorption process, a precursor adsorption process, an atomic layer forming process, and a purging process for filling the bottom gap BG.

The ALD apparatus 10 may operate as shown in FIG. 3A in the inhibitor adsorption process and the atomic layer forming process for filling the bottom gap BG. In addition, the ALD apparatus 10 may control the gas supply source 300 to respectively supply the precursor gas and the purge gas to the second gas supply pipe 302 in the precursor adsorption process and the purging process. Here, the purging process is a process performed between each of the inhibitor adsorption process, the precursor adsorption process, and the atomic layer forming process, and may be a process of removing reaction by-products or residual reactants remaining inside the main chamber 100. The purge gas may be a gas used in the purging process. For example, the purge gas may be nitrogen gas or argon gas.

The inhibitor adsorption process, the precursor adsorption process, and the atomic layer forming process for filling the bottom gap BG may be sequentially performed, and may constitute a first cycle. The first cycle may still include purging processes between above mentioned processes of the first cycle. The first cycle may be repeated n times (multiple times). For example, the ALD apparatus 10 may repeat the first cycle including the inhibitor adsorption process, the precursor adsorption process, and the atomic layer forming process n times (multiple times) to form an atomic layer in the entire region of the bottom gap BG without any void. However, when the first cycle is repeated n times (multiple times), the inhibitor adsorption process may be omitted as necessary. For example, when the processes for filling the bottom gap BG are performed, the inhibitor adsorption process may be omitted in certain cycle/sequence such that the number of performing the inhibitor adsorption process is less than the number of performing the atomic layer forming process in certain embodiments. For example, when an inhibitor layer adsorbed on an upper sidewall of the trench TR remains after the first cycle is performed once (e.g., for the first time), the inhibitor adsorption process may be omitted, and the precursor adsorption process may be performed in a subsequent time. However, as described above, the purging process may be performed after/before each process without omission.

The top gap filling process may include an inhibitor adsorption process, a precursor adsorption process, an atomic layer forming process, and a purging process for filling the top gap TG.

The ALD apparatus 10 may operate as shown in FIG. 3B in the inhibitor adsorption process and the atomic layer forming process for filling the top gap TG. In addition, the ALD apparatus 10 may control the gas supply source 300 to respectively supply the precursor gas and the purge gas to the second gas supply pipe 302 in the precursor adsorption process and the purging process.

The inhibitor adsorption process, the precursor adsorption process, and the atomic layer forming process for filling the top gap TG may be sequentially performed, and may constitute a second cycle. The second cycle may still include purging processes between above mentioned processes of the second cycle. The second cycle may be repeated n times (multiple times). However, when the second cycle is repeated n times (multiple times), the inhibitor adsorption process may be omitted as necessary. For example, when the processes for filling the top gap TG are performed, the inhibitor adsorption process may be omitted in certain cycle/sequence such that the number of times of performing the inhibitor adsorption process is less than the number of times of performing the atomic layer forming process in certain embodiments.

The ALD apparatus 10 according to an embodiment may perform an overhang etching process when an overhang occurs during the bottom gap filling process and/or the top gap filling process. The overhang etching process may include a first etching process and a second etching process. The ALD apparatus 10 may operate as shown in FIG. 3C in the first etching process, and may operate as shown in FIG. 3D in the second etching process.

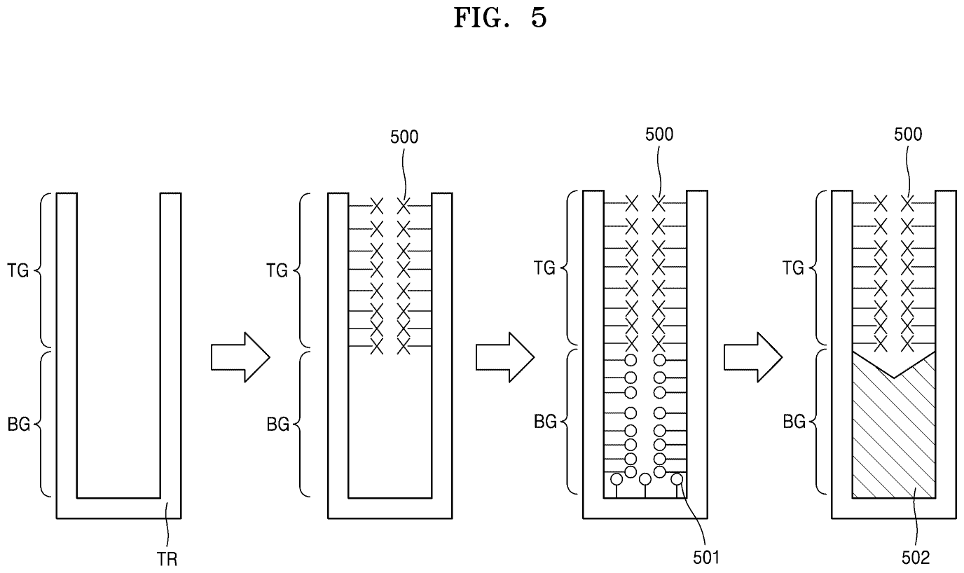

FIG. 5 is a diagram for describing a bottom gap filling process according to an embodiment.

Referring to FIG. 5, the ALD apparatus 10 may first perform an inhibitor adsorption process to fill the bottom gap BG.

The ALD apparatus 10 may be operated as shown in FIG. 3A to form an inhibitor layer 500 on a sidewall of the top gap TG. Subsequently, the ALD apparatus 10 may perform a purging process. Thereafter, the ALD apparatus 10 may perform a precursor adsorption process by supplying a precursor gas to the second gas supply pipe 302. In the precursor adsorption process, the precursor gas may be adsorbed onto a sidewall and the bottom surface of the bottom gap BG to form a precursor layer 501.

Subsequently, after performing the purging process, the ALD apparatus 10 may operate as shown in FIG. 3A to perform an atomic layer forming process. In the atomic layer forming process, radicals corresponding to a reaction gas may react with the precursor layer 501 to form an atomic layer 502.

FIG. 5 illustrates the atomic layer 502 filling the bottom gap BG formed through one time of the first cycle, but this is only for convenience of description. In an actual process, the atomic layer 502 filling the bottom gap BG may be formed by repeating the first cycle shown in FIG. 5 n times (multiple times).

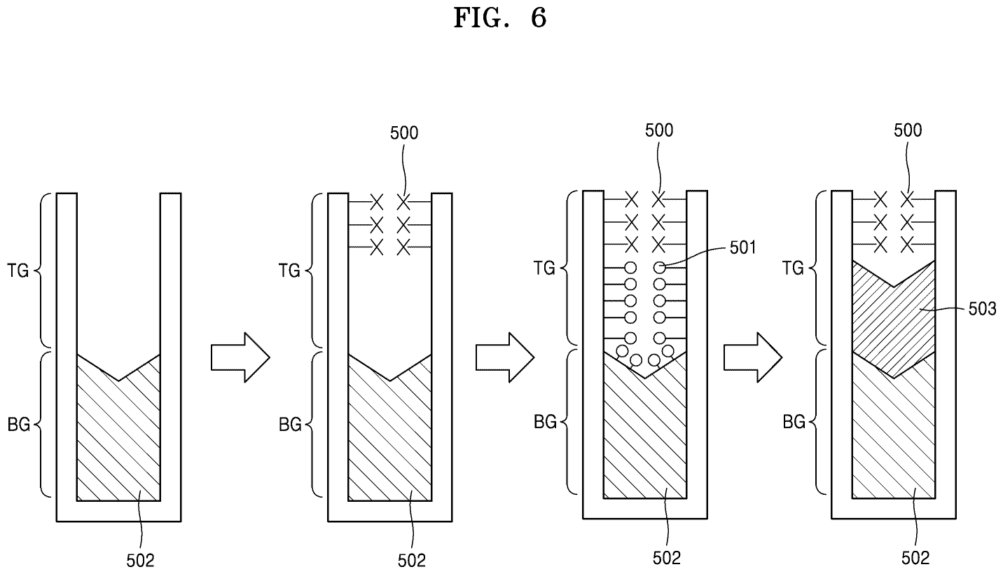

FIG. 6 is a diagram for describing a top gap filling process according to an embodiment.

Referring to FIG. 6, the ALD apparatus 10 may first perform an inhibitor adsorption process to fill the top gap TG.

The ALD apparatus 10 may operate as shown in FIG. 3B to form the inhibitor layer 500 on the uppermost sidewall of the top gap TG. Subsequently, the ALD apparatus 10 may perform a purging process.

Thereafter, the ALD apparatus 10 may perform a precursor adsorption process by supplying a precursor gas to the second gas supply pipe 302. In the precursor adsorption process, the precursor gas may be adsorbed onto a sidewall of the top gap TG, on which the inhibitor layer 500 is not formed, and onto an upper surface of the atomic layer 502 filling the bottom gap BG, to form the precursor layer 501.

Subsequently, after performing the purging process, the ALD apparatus 10 may operate as shown in FIG. 3B to perform an atomic layer forming process. In the atomic layer forming process, radicals corresponding to a reaction gas may react with the precursor layer 501 to form an atomic layer 503.

As described above, the ALD apparatus 10 may separately perform a bottom gap filling process and a top gap filling process. As a result, the ALD apparatus 10 may fill a gap of a trench with an atomic layer of uniform density without causing a density difference between the atomic layer 502 formed in the bottom gap BG and the atomic layer 503 formed in the top gap TG.

FIG. 7A is a diagram for describing a method of etching an overhang OV generated at a first vertical level LV1 according to an embodiment.

The overhang OV may be a deposition material layer that may occur during a gap filling process of a trench. For example, in the gap filling process using an ALD process, an atomic layer may be formed along a sidewall and a bottom surface of the gap. At this time, the atomic layer may be formed and grown first on an upper sidewall, and as a result, atomic layers grown on a left side wall and a right side wall may be connected to each other to generate the deposition material layer such that a cavity is formed under the deposition material layer. The deposition material layer is referred to as the overhang OV, and the overhang OV may block deposition materials, such as a precursor material and a reactant material, from moving downward.

As a result, when the overhang OV is formed, a void VO may be formed below the overhang OV. The void VO may not only adversely affect the progress of a subsequent process, but also deteriorate the electrical characteristics of a semiconductor device. Therefore, the overhang OV formed in the gap filling process through ALD may need to be removed through an overhang etching process.

As described above, the ALD apparatus 10 according to an embodiment of the inventive concept may remove the overhang OV by performing any one of a first etching process and a second etching process. For example, when a height at which the overhang OV is formed is the first vertical level LV1, the ALD apparatus 10 may remove the overhang OV based on (using) the first etching process, when the height at which the overhang OV is formed is a second vertical level LV2, the ALD apparatus 10 may remove the overhang OV based on (using) the first etching process and the second etching process, and when the height at which the overhang OV is formed is a third vertical level LV3, the ALD apparatus 10 may remove the overhang OV based on (using) the second etching process.

Here, the first vertical level LV1, the second vertical level LV2, and the third vertical level LV3 may be vertical levels divided into three ranges according to the height of the gap of the trench. The first vertical level LV1, the second vertical level LV2, and the third vertical level LV3 do not overlap each other, and the first vertical level LV1 may be located below the second vertical level LV2, and the second vertical level LV2 may be located below the third vertical level LV3. For example, assuming that the entire height of the gap of the trench is ‘H’, the first vertical level LV1 may range from the bottom surface of the gap of the trench to a height of ‘H/2’, the second vertical level LV2 may range from ‘H/2’ to a height of ‘3H/4’, and the third vertical level LV3 may range from ‘3H/4’ to the height of ‘H’. However, this is only an example, and the first vertical level LV1, the second vertical level LV2, and the third vertical level LV3 may be implemented as vertical levels in various ranges.

As shown in FIG. 7A, when the overhang OV is formed at the first vertical level LV1, the sidewall of the trench may be highly likely damaged due to the second etching process involving an ion collision. Therefore, when the overhang OV is formed at the first vertical level LV1, the ALD apparatus 10 may remove the overhang OV based on (using) the first etching process. Because the first etching process selectively etches only an oxide by using radicals and an additional gas corresponding to an etching gas, the ALD apparatus 10 may remove the overhang OV without damaging the sidewall of the trench.

FIG. 7B is a diagram for describing a method of etching an overhang generated at the second vertical level LV2 according to an embodiment.

As shown in FIG. 7B, when the overhang OV is formed at the second vertical level LV2, the ALD apparatus 10 may remove the overhang OV based on (using) the second etching process, and when it is identified that damage to a sidewall of a trench has occurred due to a second etching process, the ALD apparatus 10 may remove the overhang OV based on (using) the first etching process.

In order to prevent the damage to the sidewall, even when the overhang OV is formed at the second vertical level LV2, the overhang OV may be removed based on (using) the first etching process. However, the first etching process may have a lower etching rate than the second etching process. Therefore, the removal of the overhang OV based on (using) the first etching process may take a relatively longer time than the removal of the overhang OV based on (using) the second etching process. For example, the throughput of the second etching process may be greater than the throughput of the first etching process.

Therefore, when the overhang OV is formed at the second vertical level LV2, the ALD apparatus 10 may first remove the overhang OV based on (using) the second etching process with a great throughput. When it is identified that damage to the sidewall of the trench has occurred by an optical apparatus or an analysis apparatus, the ALD apparatus 10 may remove the remaining part of the overhang OV based on (by using) the first etching process.

FIG. 7C is a diagram for describing a method of etching an overhang generated at the third vertical level LV3 according to an embodiment.

As shown in FIG. 7C, when the overhang OV is formed at the third vertical level LV3, the ALD apparatus 10 may remove the overhang OV based on (by using) the second etching process.

When the overhang OV is formed at the third vertical level LV3, because the risk of damage to a sidewall is not great, the ALD apparatus 10 may remove the overhang OV based on (by using) the second etching process with a great throughput.

However, even though the overhang OV is formed at the third vertical level LV3, when it is identified that damage to the sidewall of the trench has occurred by an optical apparatus or an analysis apparatus, the ALD apparatus 10 may remove the remaining part of the overhang OV based on (by using) a first etching process.

In the descriptions with respect to FIGS. 7A to 7C above, it has been described that the ALD apparatus 10 may remove the overhang OV based on (using) various etching processes according to the height at which the overhang OV is formed, but this is only an example. The ALD apparatus 10 may select and perform any one of the first etching process and the second etching process based on the shape of the void VO, the size of the void VO, the required throughput, and/or whether a surface of the wafer WF is protected by a mask (e.g., a photoresist PR).

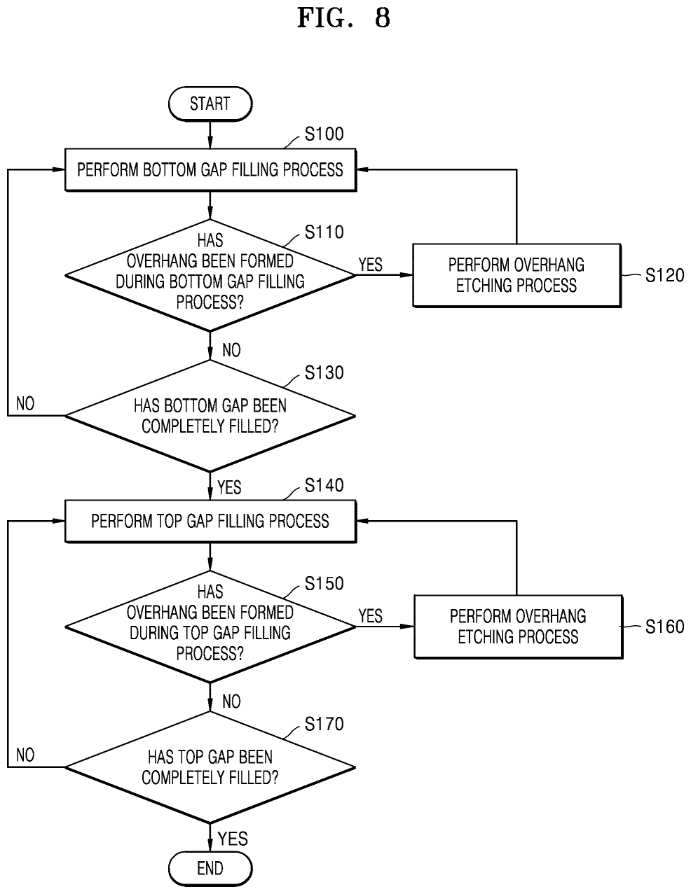

FIG. 8 is a flowchart illustrating a method of filling a gap of a trench according to an embodiment.

According to an embodiment, in operation S100, a bottom gap filling process for filling a bottom gap of the trench included in a wafer may be performed. Here, the bottom gap filling process has been described in detail with reference to FIG. 5, and thus a duplicated description of operation S100 is omitted here.

In operation S110, whether an overhang has been formed during the bottom gap filling process may be identified/decided. When it is identified/decided that the overhang is formed (S110: Y), an overhang etching process may be performed in operation S120. After the overhang is removed through the overhang etching process, operations S100 and S110 may be performed again.

When it is identified/decided that the overhang is not formed (S110: N), whether the bottom gap has been completely filled may be identified/decided in operation S130.

When it is identified/decided that the bottom gap has not been completely filled (S130: N), operations S100 and S110 may be performed again. When it is identified/decided that the bottom gap has been completely filled (S130: Y), operation S140 may be performed.

In operation S140, a top gap filling process for filling a top gap of the trench may be performed. The top gap filling process has been described in detail with reference to FIG. 6, and thus, a duplicated description of operation S140 is omitted here.

In operation S150, whether an overhang has been formed during the top gap filling process may be identified/decided. When it is identified/decided that the overhang is formed (S150: Y), the overhang etching process may be performed in operation S160. After the overhang is removed through the overhang etching process, operations S140 and S150 may be performed again.

When it is identified/decided that the overhang is not formed (S150: N), whether the top gap has been completely filled may be identified/decided in operation S170.

When it is identified/decided that the top gap has not been completely filled (S170: N), operations S140 and S150 may be performed again. When it is identified/decided that the top gap has been completely filled (S170: Y), an ALD process may end.

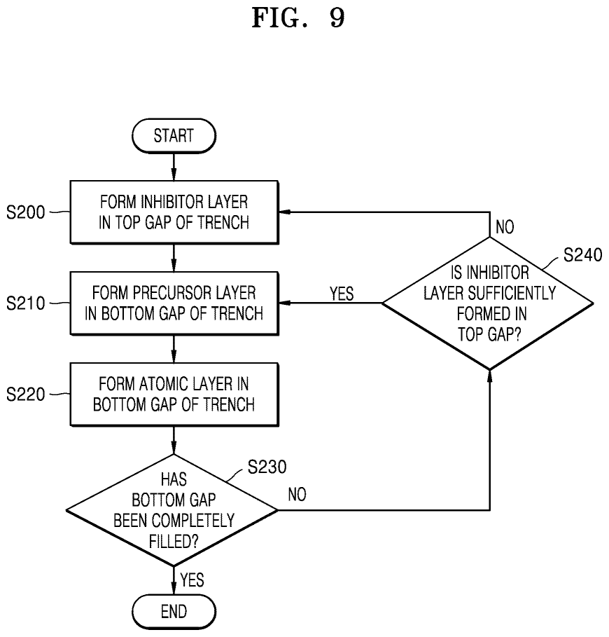

FIG. 9 is a flowchart for describing a method of filling a bottom gap of a trench according to an embodiment.

Here, “operation S100” of FIG. 8 may include “operations S200 to S240” of FIG. 9.

In operation S200, an inhibitor layer may be formed in a top gap of the trench. In operation S210, a precursor layer may be formed in the bottom gap of the trench. In operation S220, an atomic layer may be formed in the bottom gap of the trench. In operation S230, whether the bottom gap has been completely filled may be identified/decided.

When it is identified/decided that the bottom gap has been completely filled (S230: Y), the bottom gap filling process may end. When it is identified/decided that the bottom gap has not been completely filled (S230: N), whether an inhibitor layer is sufficiently formed/remained in the top gap may be identified/decided in operation S240.

When it is identified/decided that the inhibitor layer is not sufficiently formed/remained in the top gap (S240: N), operations S200 to S230 may be performed again. When it is identified/decided that the inhibitor layer is sufficiently formed/remained in the top gap (S240: Y), operations S210 to S230 may be performed again.

The inhibitor layer forming process, the precursor layer forming process, and the atomic layer forming process for filling the bottom gap described above are described in detail with reference to FIG. 5, and thus duplicated descriptions thereof are omitted here.

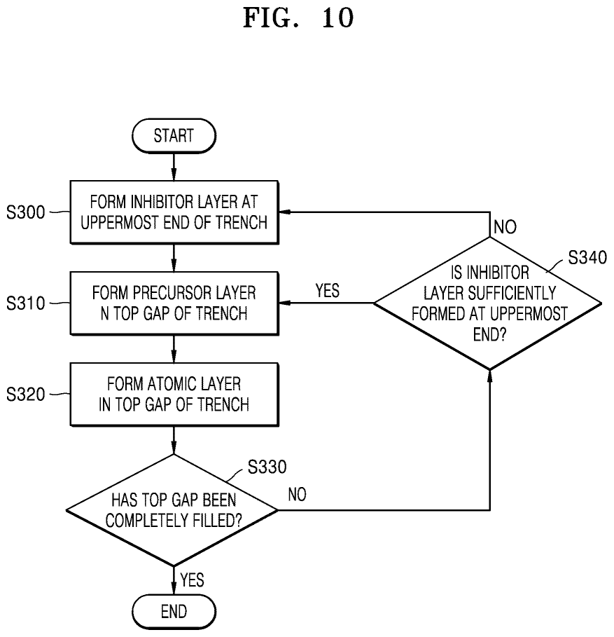

FIG. 10 is a flowchart for describing a method of filling a top gap of a trench according to an embodiment.

Here, “operation S140” of FIG. 8 may include “operations S300 to S340” of FIG. 10.

In operation S300, an inhibitor layer may be formed on the uppermost end of the trench. In operation S310, a precursor layer may be formed in the top gap of the trench. In operation S320, an atomic layer may be formed in the top gap of the trench. In operation S330, whether the top gap has been completely filled may be identified/decided.

When it is identified/decided that the top gap has been completely filled (S330: Y), a top gap filling process may end. When it is identified/decided that the bottom gap has not been completely filled (S330: N), whether an inhibitor layer is sufficiently formed/remained at the uppermost end may be identified/decided in operation S340.

When it is identified/decided that the inhibitor layer is not sufficiently formed at the uppermost end (S340: N), operations S300 to S330 may be performed again. In addition, when it is identified/decided that the inhibitor layer is sufficiently formed/remained at the uppermost end (S340: Y), operations S310 to S330 may be performed again.

The inhibitor layer forming process, the precursor layer forming process, and the atomic layer forming process for filling the top gap described above are described in detail with reference to FIG. 6, and thus duplicated descriptions thereof are omitted here.

The ALD apparatus 10 according to an embodiment of the inventive concept may perform various types of processes by using at least one of radicals, ions, or gas particles. For example, the ALD apparatus 10 may separately perform a bottom gap filling process and a top gap filling process of a trench. The ALD apparatus 10 may separately perform the two processes, and thus, there is no difference between the density of an atomic layer filling a bottom gap and the density of an atomic layer filling a top gap, and an atomic layer density distribution may be uniform over the entire gap region. In addition, the ALD apparatus 10 may efficiently remove an overhang through a first etching process and/or a second etching process when the overhang occurs, and thus, the gap may be filled without voids.

In the present disclosure, in addition to structures of ALD apparatus, processes of forming ALD layers on a wafer WF are also disclosed. The processes of forming ALD layers on a wafer WF may be parts of methods of manufacturing semiconductor devices. Therefore, the methods of manufacturing semiconductor devices as well as the ALD apparatus and the processes of forming ALD layers are within the scope of the present disclosure.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. An atomic layer deposition (ALD) apparatus comprising:
a gas supply source configured to supply a first gas and a second gas to a first gas supply pipe and a second gas supply pipe, respectively;
an upper plasma chamber configured to receive the first gas from the first gas supply pipe and generate first radicals and first ions;
a main chamber disposed below the upper plasma chamber;
an electrostatic chuck configured to accommodate a wafer and disposed at a bottom of the main chamber;
an ion-blocking structure disposed between the upper plasma chamber and the main chamber, and configured to allow movement of the first radicals from the upper plasma chamber toward the main chamber, and block movement of the first ions; and
a shower head disposed between the main chamber and the ion-blocking structure and comprising a plurality of first holes and a plurality of second holes,
wherein the plurality of first holes penetrate from an upper surface of the shower head to a lower surface of the shower head, and are configured to supply the first radicals into the main chamber, and
the plurality of second holes are configured to supply, into the main chamber, the second gas supplied from the second gas supply pipe.

2. The ALD apparatus of claim 1, wherein
the ion-blocking structure includes a plurality of through holes connected to the plurality of first holes, respectively,
the plurality of second holes extend from the lower surface of the shower head to a middle level of the shower head, and
the plurality of first holes and the plurality of second holes are arranged alternately with each other.

3. The ALD apparatus of claim 2, wherein
the shower head includes first to n^{th} circular flow paths formed in the shower head in a circumferential direction with respect to a central axis of the shower head,
the plurality of second holes are grouped into first to n^{th} groups according to distances from a center of the shower head in a radial direction,
the plurality of second holes respectively included in the first to n^{th} groups are disposed on lower surfaces of the first to n^{th} circular flow paths, respectively,
each of the first to n^{th} circular flow paths is connected to a gas inlet hole extending from a side surface of the shower head to inside of the shower head, and
the gas inlet hole is connected to the second gas supply pipe to supply gas to each of the first to n^{th} circular flow paths in a horizontal direction.

4. The ALD apparatus of claim 3, wherein the plurality of first holes are disposed between two adjacent circular paths among the first to n^{th} circular flow paths.

5. The ALD apparatus of claim 1, further comprising: a controller,
wherein the controller is configured to
control the gas supply source to supply an inhibitor gas to the first gas supply pipe, in an inhibitor adsorption mode for filling a bottom gap of a trench included in the wafer,
control the gas supply source to supply a precursor gas to the second gas supply pipe, in a precursor adsorption mode for filling the bottom gap, and
control the gas supply source to supply a reaction gas to the first gas supply pipe, in an atomic layer formation mode for filling the bottom gap.

6. The ALD apparatus of claim 5, further comprising: a plasma ignition apparatus configured to generate main plasma using the second gas inside the main chamber,
wherein the main plasma includes second radicals and second ions, and
the controller is configured to
control the gas supply source to supply the inhibitor gas to the first gas supply pipe and the second gas supply pipe and control the plasma ignition apparatus to generate the main plasma, in an inhibitor adsorption mode for filling a top gap of the trench,
control the gas supply source to supply the precursor gas to the second gas supply pipe, in a precursor adsorption mode for filling the top gap, and
control the gas supply source to supply the reaction gas to the first gas supply pipe and the second gas supply pipe and control the plasma ignition apparatus to generate the main plasma, in an atomic layer formation mode for filling the top gap.

7. The ALD apparatus of claim 6, wherein
the controller is configured to control the plasma ignition apparatus to increase radio frequency (RF) power applied to inside of the main chamber, to increase an ion ratio inside the main chamber,
the ion ratio is a ratio of a density of the second ions to a radical density, and
the radical density is a value obtained by summing a density of the first radicals and a density of the second radicals.

8. The ALD apparatus of claim 7, wherein the controller is configured to control the gas supply source to supply the second gas at a flow rate higher than a flow rate of the first gas, to increase the ion ratio inside the main chamber.

9. The ALD apparatus of claim 6, wherein
the controller is configured to
control the gas supply source to supply an etching gas to the first gas supply pipe and to supply an additional gas to the second gas supply pipe, in a first etching mode,
control the plasma ignition apparatus to supply the etching gas to the second gas supply pipe and generate the main plasma, in a second etching mode,
the first etching mode is an overhang etching mode based on a selective chemical reaction with an oxide, and
the second etching mode is an overhang etching mode involving ion collision.

10. An atomic layer deposition (ALD) apparatus comprising:
a main chamber;
a gas supply source configured to supply a first gas and a second gas to a first gas supply pipe and a second gas supply pipe, respectively;
an electrostatic chuck configured to accommodate a wafer and disposed at a bottom of the main chamber;
an upper plasma chamber disposed at a top of the main chamber and configured to receive the first gas from the first gas supply pipe;
an ion-blocking structure disposed between the main chamber and the upper plasma chamber and configured to block movement of ions from the upper plasma chamber toward the main chamber;
a shower head disposed between the ion-blocking structure and the main chamber and comprising a plurality of first holes and a plurality of second holes;
a first plasma ignition apparatus configured to generate upper plasma inside the upper plasma chamber; and
a second plasma ignition apparatus configured to generate main plasma inside the main chamber,
wherein the upper plasma comprises first radicals and first ions, corresponding to the first gas,
the main plasma includes second radicals and second ions, corresponding to the second gas,
the plurality of first holes are configured to supply the first radicals into the main chamber, and
the plurality of second holes are configured to supply a gas supplied from the second gas supply pipe into the main chamber.

11. The ALD apparatus of claim 10, wherein
the ion-blocking structure includes a plurality of through holes connected to the plurality of first holes, respectively,
the shower head includes first to n^{th} circular flow paths formed in the shower head in a circumferential direction with respect to a central axis of the shower head,
the plurality of second holes are grouped into first to n^{th} groups according to distances from a center of the shower head in a radial direction, and
the plurality of second holes respectively included in the first to n^{th} groups are disposed on lower surfaces of the first to n^{th} circular flow paths, respectively.

12. The ALD apparatus of claim 11, wherein
the plurality of first holes are disposed between two adjacent circular paths among the first to n^{th} circular flow paths,
each of the first to n^{th} circular flow paths is connected to a gas inlet hole extending from a side surface of the shower head to inside of the shower head, and
the gas inlet hole is connected to the second gas supply pipe to supply gas to each of the first to n^{th} circular flow paths in a horizontal direction.

13. The ALD apparatus of claim 10, further comprising: a controller,
wherein the controller is configured to
control the gas supply source to supply an inhibitor gas to the first gas supply pipe and control the first plasma ignition apparatus to generate the upper plasma, in an inhibitor adsorption mode for filling a bottom gap of a trench included in the wafer,
control the gas supply source to supply a precursor gas to the second gas supply pipe, in a precursor adsorption mode for filling the bottom gap, and
control the gas supply source to supply a reaction gas to the first gas supply pipe and control the first plasma ignition apparatus to generate the upper plasma, in an atomic layer formation mode for filling the bottom gap.

14. The ALD apparatus of claim 13, wherein the controller is configured to
control the gas supply source to supply the inhibitor gas to the first gas supply pipe and the second gas supply pipe and control the first plasma ignition apparatus and the second plasma ignition apparatus to generate the upper plasma and the main plasma, in an inhibitor adsorption mode for filling a top gap of the trench,
control the gas supply source to supply the precursor gas to the second gas supply pipe, in a precursor adsorption mode for filling the top gap, and
control the gas supply source to supply the reaction gas to the first gas supply pipe and the second gas supply pipe and control the first plasma ignition apparatus and the second plasma ignition apparatus to generate the upper plasma and the main plasma, in an atomic layer formation mode for filling the top gap.

15. The ALD apparatus of claim 13, wherein
the controller is configured to control the first plasma ignition apparatus to increase radio frequency (RF) power applied to inside of the upper plasma chamber, to reduce an ion ratio inside the main chamber,
the ion ratio is a ratio of a density of the second ions to a radical density, and
the radical density is a sum of a density of the first radicals and a density of the second radicals.

16. The ALD apparatus of claim 15, wherein the controller is configured to control the gas supply source to supply the second gas at a flow rate higher than a flow rate of the first gas, to increase the ion ratio inside the main chamber.

17. An atomic layer deposition (ALD) apparatus comprising:
a gas supply source configured to supply a first gas and a second gas to a first gas supply pipe and a second gas supply pipe, respectively;
an upper plasma chamber to receive the first gas from the first gas supply pipe;
a main chamber disposed below the upper plasma chamber;
an ion-blocking structure disposed between the upper plasma chamber and the main chamber, and configured to block movement of ions from the upper plasma chamber toward the main chamber;
a shower head in contact with a lower surface of the ion-blocking structure and comprising a plurality of first holes and a plurality of second holes;
an electrostatic chuck disposed at a bottom of the main chamber and configured to fix a wafer;
a bias power supply configured to apply a bias potential to the wafer;
a first plasma ignition apparatus configured to generate upper plasma inside the upper plasma chamber; and
a second plasma ignition apparatus configured to generate main plasma inside the main chamber,
wherein the upper plasma comprises first radicals and first ions, corresponding to a gas supplied from the first gas supply pipe,
the main plasma comprises second radicals and second ions, corresponding to a gas supplied from the second gas supply pipe,
the plurality of first holes are configured to supply the first radicals into the main chamber, and
the plurality of second holes are configured to supply, into the main chamber, the gas supplied from the second gas supply pipe.

18. The ALD apparatus of claim 17, wherein
the ion-blocking structure includes a plurality of through holes penetrating from an upper surface of the ion-blocking structure to a lower surface of the ion-blocking structure,
the shower head includes first to n^{th} circular flow paths formed in the shower head in a circumferential direction with respect to a central axis of the shower head,
the plurality of through holes are connected to the plurality of first holes, respectively,
the plurality of second holes are grouped into first to n^{th} groups according to a distance from a center of the shower head in a radial direction, and
the plurality of second holes respectively included in the first to n^{th} groups are disposed on lower surfaces of the first to n^{th} circular flow paths formed in the shower head, respectively,
each of the first to n^{th} circular flow paths is connected to a gas inlet hole extending from a side surface of the shower head to inside of the shower head, and
the plurality of first holes and the plurality of second holes are arranged alternately with each other.

19. The ALD apparatus of claim 17, wherein
the first plasma ignition apparatus is configured to increase radio frequency (RF) power applied to inside of the upper plasma chamber, to reduce an ion ratio inside the main chamber,
the ion ratio is a ratio of a density of the second ions to a radical density, and
the radical density is a sum of a density of the first radicals and a density of the second radicals.

20. The ALD apparatus of claim 17, wherein
the gas supply source includes an inhibitor gas storage chamber, a reaction gas storage chamber, an etching gas storage chamber, a precursor gas storage chamber, and a purge gas storage chamber,
the inhibitor gas storage chamber, the reaction gas storage chamber, and the etching gas storage chamber are connected to the first gas supply pipe and the second gas supply pipe, and
the precursor gas storage chamber and the purge gas storage chamber are connected to the second gas supply pipe.
